(19) United States
(12) Patent Application Publication
(10) Pub. No.: US 2018/0138292 A1
(43) Pub. Date: May 17, 2018

(54) METHODS AND APPARATUS FOR THREE-DIMENSIONAL NONVOLATILE MEMORY

(71) Applicant: SANDISK TECHNOLOGIES LLC, Plano, TX (US)

(72) Inventors: Alvaro Padilla, San Jose, CA (US); Bijesh Rajamohanan, Fremont, CA (US)

(73) Assignee: SANDISK TECHNOLOGIES LLC, Plano, TX (US)

(21) Appl. No.: 15/349,382

(22) Filed: Nov. 11, 2016

(51) Int. Cl. H01L 29/66; H01L 27/24; H01L 27/115; H01L 45/00

(52) U.S. Cl. CPC H01L 29/66666; H01L 27/2454; H01L 27/11582; H01L 45/16; H01L 29/66833; H01L 45/06; H01L 45/1233; H01L 27/11568

(57) ABSTRACT

A method is provided that includes forming a bit line above a substrate, forming a word line above the substrate, and forming a non-volatile memory cell between the bit line and the word line. The non-volatile memory cell includes a non-volatile memory material coupled in series with an isolation element. The isolation element includes a first portion disposed between a first electrode and a second electrode, the first electrode includes a first material having a first work function, the second electrode includes a second material having second work function, and the first work function does not equal the second work function.

### BACKGROUND

Semiconductor memory is widely used in various electronic devices such as mobile computing devices, mobile phones, solid-state drives, digital cameras, personal digital assistants, medical electronics, servers, and non-mobile computing devices. Semiconductor memory may include non-volatile memory or volatile memory. A non-volatile memory device allows information to be stored or retained even when the non-volatile memory device is not connected to a power source.

One example of non-volatile memory uses non-volatile memory cells that include reversible resistance-switching memory elements that may be reversibly switched between a high resistance state and a low resistance state. One example of a reversible resistance-switching memory element includes a metal oxide as the reversible resistance-switching memory material disposed between first and second conductors.

In response to appropriate voltages, a reversible resistance-switching memory element may switch consistently between a high resistance (RESET) state and a low resistance (SET) state.

In recent years, non-volatile memory devices have been scaled to reduce the cost per bit. However, as process geometries shrink, many design and process challenges are presented.

### BRIEF DESCRIPTION OF THE DRAWINGS

FIG. 1A depicts an embodiment of a memory system and a host.

FIG. 1B depicts an embodiment of memory core control circuits.

FIG. 1C depicts an embodiment of a memory core.

FIG. 1D depicts an embodiment of a memory bay.

FIG. 1E depicts an embodiment of a memory block.

FIG. 1F depicts another embodiment of a memory bay.

FIG. 2A depicts an embodiment of a portion of a monolithic three-dimensional memory array.

FIG. 2B depicts an embodiment of a portion of a monolithic three-dimensional memory array that includes vertical strips of a non-volatile memory material.

FIGS. 2C1-2C3 depict an embodiment of a portion of a monolithic three-dimensional memory array.

FIG. 3A depicts a diagram of an example current versus voltage characteristic for an example isolation element.

FIG. 3B depicts an embodiment of an amorphous silicon isolation element.

FIG. 4A-4E depict various views of an embodiment monolithic three-dimensional memory array.

FIGS. 5A1-5J3 are cross-sectional views of a portion of a substrate during an example fabrication of the monolithic three-dimensional memory array of FIGS. 4A-4E.

### DETAILED DESCRIPTION

Technology is described for including isolation elements in a non-volatile memory cell, such as a reversible resistance-switching memory cell. The non-volatile memory cell is disposed between a word line and a vertical bit line. The non-volatile memory cell includes an isolation element that includes a semiconductor material disposed between a first metal and a second metal. The semiconductor material may be amorphous silicon. The first metal has a first work function, the second metal has a second work function, and the first work function is not the same as the second work function.

In some embodiments, a memory array may include a cross-point memory array. A cross-point memory array may refer to a memory array in which two-terminal non-volatile memory cells are placed at the intersections of a first set of control lines (e.g., word lines) arranged in a first direction and a second set of control lines (e.g., bit lines) arranged in a second direction perpendicular to the first direction. The two-terminal non-volatile memory cells may include a reversible resistance-switching memory element, such as a phase change material, a ferroelectric material, or a metal oxide (e.g., hafnium oxide), disposed between first and second conductors. In some embodiments, each non-volatile memory cell in a cross-point memory array includes a reversible resistance-switching memory element in series with a steering element or an isolation element, such as one or more diodes, to reduce leakage currents. In other cross-point memory arrays, the non-volatile memory cells do not include isolation elements.

In an embodiment, a non-volatile storage system may include one or more two-dimensional arrays of non-volatile memory cells. The non-volatile memory cells within a two-dimensional memory array may form a single layer of non-volatile memory cells and may be selected via control lines (e.g., word lines and bit lines) in the X and Y directions. In another embodiment, a non-volatile storage system may include one or more monolithic three-dimensional memory arrays in which two or more layers of non-volatile memory cells may be formed above a single substrate without any intervening substrates.

In some cases, a three-dimensional memory array may include one or more vertical columns of non-volatile memory cells located above and orthogonal to a substrate. In an example, a non-volatile storage system may include a memory array with vertical bit lines or bit lines that are arranged orthogonal to a semiconductor substrate. The substrate may include a silicon substrate. The memory array may include rewriteable non-volatile memory cells, wherein each non-volatile memory cell includes a reversible resistance-switching memory element and an isolation element in series with the reversible resistance-switching memory element. In other embodiments, each non-volatile memory cell includes a reversible resistance-switching memory element without an isolation element in series with the reversible resistance-switching memory element.

In some embodiments, a non-volatile storage system may include a non-volatile memory that is monolithically formed in one or more physical levels of arrays of non-volatile memory cells having an active area disposed above a silicon substrate. The non-volatile storage system may also include circuitry associated with the operation of the non-volatile memory cells (e.g., decoders, state machines, page registers, and/or control circuitry for controlling reading, programming and erasing of the non-volatile memory cells). The circuitry associated with the operation of the non-volatile memory cells may be located above the substrate or within the substrate.

In some embodiments, a non-volatile storage system may include a monolithic three-dimensional memory array. The monolithic three-dimensional memory array may include one or more levels of non-volatile memory cells. Each non-volatile memory cell within a first level of the one or more levels of non-volatile memory cells may include an active area that is located above a substrate (e.g., above a single-crystal substrate or a crystalline silicon substrate). In one example, the active area may include a semiconductor junction (e.g., a P-N junction). The active area may include a portion of a source or drain region of a transistor. In another example, the active area may include a channel region of a transistor.

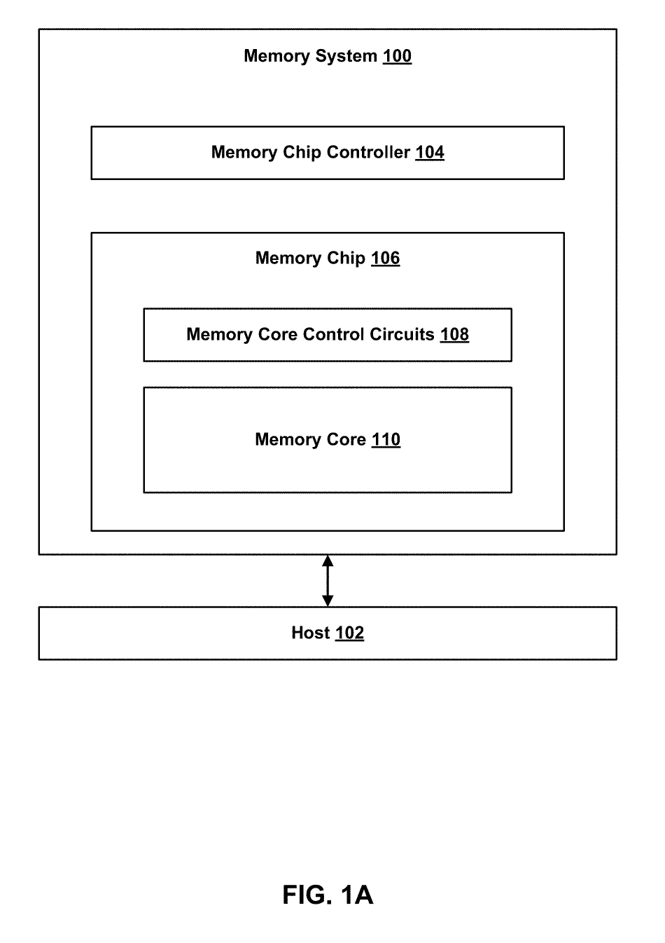

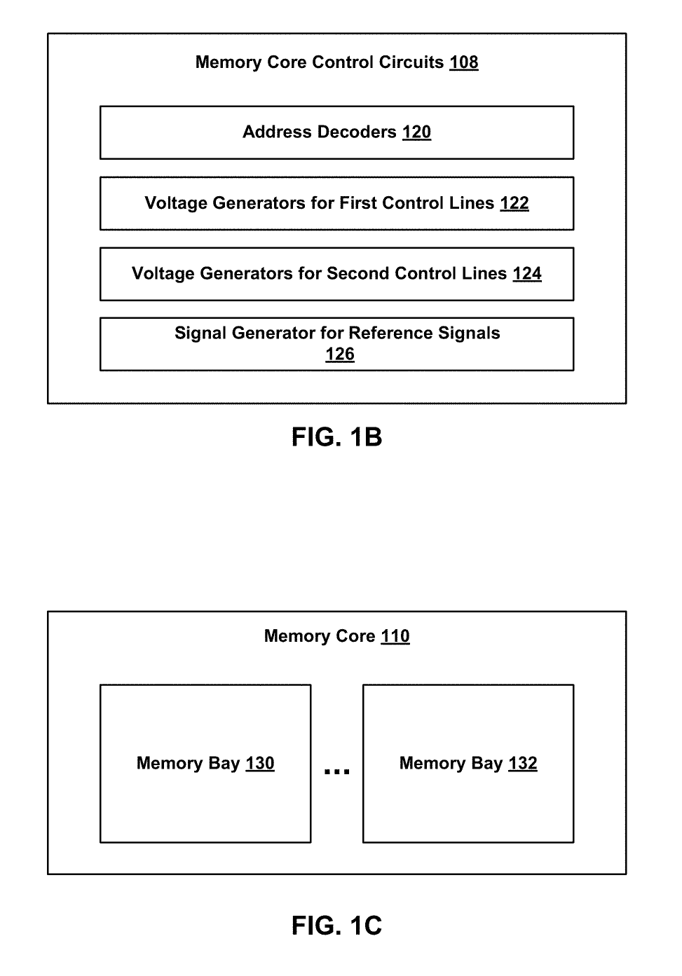

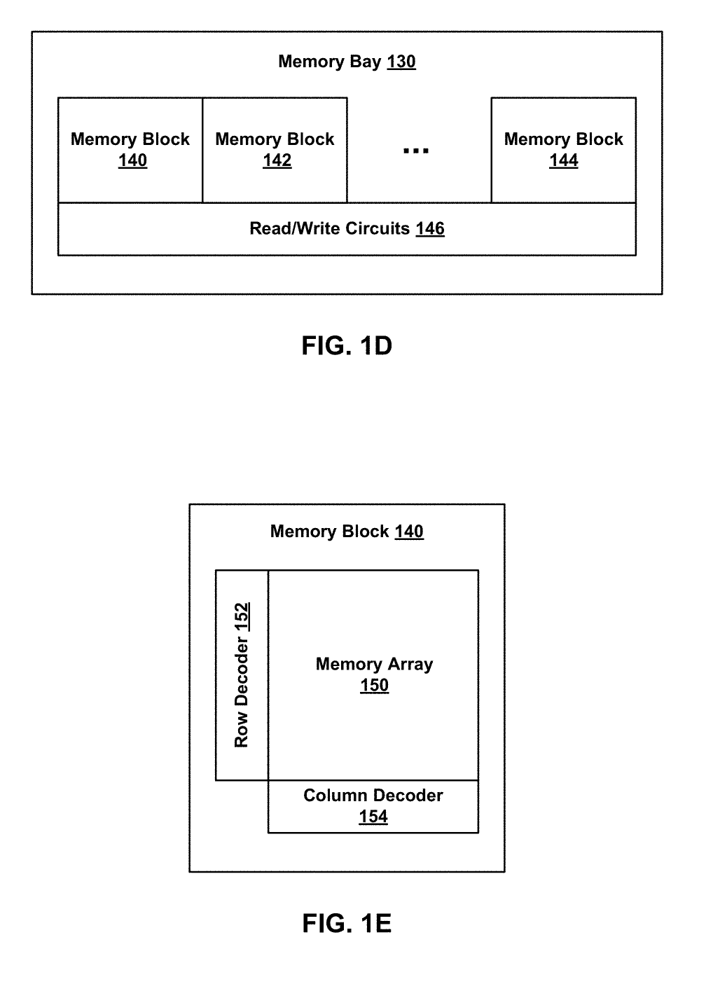

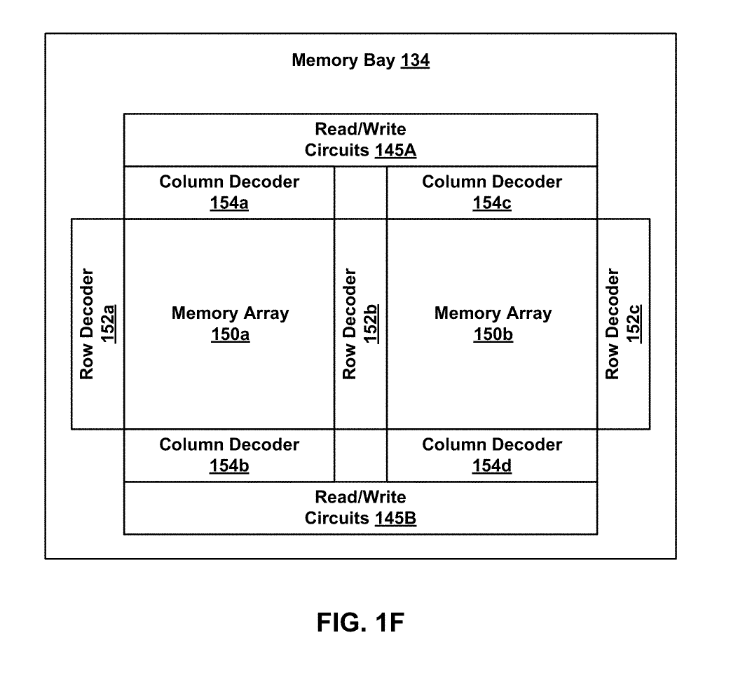

FIG. 1A depicts one embodiment of a memory system 100 and a host 102. Memory system 100 may include a non-volatile storage system interfacing with host 102 (e.g., a mobile computing device). In some cases, memory system 100 may be embedded within host 102. In other cases, memory system 100 may include a memory card. As depicted, memory system 100 includes a memory chip controller 104 and a memory chip 106. Although a single memory chip 106 is depicted, memory system 100 may include more than one memory chip (e.g., four, eight or some other number of memory chips). Memory chip controller 104 may receive data and commands from host 102 and provide memory chip data to host 102.

Memory chip controller 104 may include one or more state machines, page registers, SRAM, and control circuitry for controlling the operation of memory chip 106. The one or more state machines, page registers, SRAM, and control circuitry for controlling the operation of memory chip 106 may be referred to as managing or control circuits. The managing or control circuits may facilitate one or more memory array operations, such as forming, erasing, programming, and reading operations.

In some embodiments, the managing or control circuits (or a portion of the managing or control circuits) for facilitating one or more memory array operations may be integrated within memory chip 106. Memory chip controller 104 and memory chip 106 may be arranged on a single integrated circuit. In other embodiments, memory chip controller 104 and memory chip 106 may be arranged on different integrated circuits. In some cases, memory chip controller 104 and memory chip 106 may be integrated on a system board, logic board, or a PCB.

Memory chip 106 includes memory core control circuits 108 and a memory core 110. Memory core control circuits 108 may include logic for controlling the selection of memory blocks (or arrays) within memory core 110, controlling the generation of voltage references for biasing a particular memory array into a read or write state, and generating row and column addresses.

Memory core 110 may include one or more two-dimensional arrays of non-volatile memory cells or one or more three-dimensional arrays of non-volatile memory cells. In an embodiment, memory core control circuits 108 and memory core 110 are arranged on a single integrated circuit. In other embodiments, memory core control circuits 108 (or a portion of memory core control circuits 108) and memory core 110 may be arranged on different integrated circuits.

A memory operation may be initiated when host 102 sends instructions to memory chip controller 104 indicating that host 102 would like to read data from memory system 100 or write data to memory system 100. In the event of a write (or programming) operation, host 102 will send to memory chip controller 104 both a write command and the data to be written. The data to be written may be buffered by memory chip controller 104 and error correcting code (ECC) data may be generated corresponding with the data to be written. The ECC data, which allows data errors that occur during transmission or storage to be detected and/or corrected, may be written to memory core 110 or stored in non-volatile memory within memory chip controller 104. In an embodiment, the ECC data are generated and data errors are corrected by circuitry within memory chip controller 104.

Memory chip controller 104 controls operation of memory chip 106. In one example, before issuing a write operation to memory chip 106, memory chip controller 104 may check a status register to make sure that memory chip 106 is able to accept the data to be written. In another example, before issuing a read operation to memory chip 106, memory chip controller 104 may pre-read overhead information associated with the data to be read. The overhead information may include ECC data associated with the data to be read or a redirection pointer to a new memory location within memory chip 106 in which to read the data requested. Once a read or write operation is initiated by memory chip controller 104, memory core control circuits 108 may generate the appropriate bias voltages for word lines and bit lines within memory core 110, and generate the appropriate memory block, row, and column addresses.

In some embodiments, one or more managing or control circuits may be used for controlling the operation of a memory array. The one or more managing or control circuits may provide control signals to a memory array to perform an erase operation, a read operation, and/or a write operation on the memory array. In one example, the one or more managing or control circuits may include any one of or a combination of control circuitry, state machine, decoders, sense amplifiers, read/write circuits, and/or controllers. The one or more managing circuits may perform or facilitate one or more memory array operations including erasing, programming, or reading operations. In one example, one or more managing circuits may include an on-chip memory controller for determining row and column address, word line and bit line addresses, memory array enable signals, and data latching signals.

FIG. 1B depicts one embodiment of memory core control circuits 108. As depicted, memory core control circuits 108 include address decoders 120, voltage generators for first control lines 122, voltage generators for second control lines 124 and signal generators for reference signals 126 (described in more detail below). Control lines may include word lines, bit lines, or a combination of word lines and bit lines. First control lines may include first (e.g., selected) word lines and/or first (e.g., selected) bit lines that are used to place non-volatile memory cells into a first (e.g., selected) state. Second control lines may include second (e.g., unselected) word lines and/or second (e.g., unselected) bit lines that are used to place non-volatile memory cells into a second (e.g., unselected) state.

Address decoders 120 may generate memory block addresses, as well as row addresses and column addresses for a particular memory block. Voltage generators (or voltage regulators) for first control lines 122 may include one or more voltage generators for generating first (e.g., selected) control line voltages. Voltage generators for second control lines 124 may include one or more voltage generators for generating second (e.g., unselected) control line voltages. Signal generators for reference signals 126 may include one or more voltage and/or current generators for generating reference voltage and/or current signals.

FIGS. 1C-1F depict one embodiment of a memory core organization that includes a memory core having multiple memory bays, and each memory bay having multiple memory blocks. Although a memory core organization is disclosed where memory bays include memory blocks, and memory blocks include a group of non-volatile memory cells, other organizations or groupings also can be used with the technology described herein.

FIG. 1C depicts an embodiment of memory core 110 of FIG. 1A. As depicted, memory core 110 includes memory bay 130 and memory bay 132. In some embodiments, the number of memory bays per memory core can differ for different implementations. For example, a memory core may include only a single memory bay or multiple memory bays (e.g., 16 or other number of memory bays).

FIG. 1D depicts an embodiment of memory bay 130 in FIG. 1C. As depicted, memory bay 130 includes memory blocks 140-144 and read/write circuits 146. In some embodiments, the number of memory blocks per memory bay may differ for different implementations. For example, a memory bay may include one or more memory blocks (e.g., 32 or other number of memory blocks per memory bay). Read/write circuits 146 include circuitry for reading and writing non-volatile memory cells within memory blocks 140-144.

As depicted, read/write circuits 146 may be shared across multiple memory blocks within a memory bay. This allows chip area to be reduced because a single group of read/write circuits 146 may be used to support multiple memory blocks. However, in some embodiments, only a single memory block may be electrically coupled to read/write circuits 146 at a particular time to avoid signal conflicts.

In some embodiments, read/write circuits 146 may be used to write one or more pages of data into memory blocks 140-144 (or into a subset of the memory blocks). The non-volatile memory cells within memory blocks 140-144 may permit direct over-writing of pages (i.e., data representing a page or a portion of a page may be written into memory blocks 140-144 without requiring an erase or reset operation to be performed on the non-volatile memory cells prior to writing the data).

In one example, memory system 100 of FIG. 1A may receive a write command including a target address and a set of data to be written to the target address. Memory system 100 may perform a read-before-write (RBW) operation to read the data currently stored at the target address and/or to acquire overhead information (e.g., ECC information) before performing a write operation to write the set of data to the target address.

In some cases, read/write circuits 146 may be used to program a particular non-volatile memory cell to be in one of three or more data/resistance states (i.e., the particular non-volatile memory cell may include a multi-level non-volatile memory cell). In one example, read/write circuits 146 may apply a first voltage difference (e.g., 2V) across the particular non-volatile memory cell to program the particular non-volatile memory cell into a first state of the three or more data/resistance states or a second voltage difference (e.g., 1V) across the particular non-volatile memory cell that is less than the first voltage difference to program the particular non-volatile memory cell into a second state of the three or more data/resistance states.

Applying a smaller voltage difference across the particular non-volatile memory cell may cause the particular non-volatile memory cell to be partially programmed or programmed at a slower rate than when applying a larger voltage difference. In another example, read/write circuits 146 may apply a first voltage difference across the particular non-volatile memory cell for a first time period to program the particular non-volatile memory cell into a first state of the three or more data/resistance states, and apply the first voltage difference across the particular non-volatile memory cell for a second time period less than the first time period. One or more programming pulses followed by a non-volatile memory cell verification phase may be used to program the particular non-volatile memory cell to be in the correct state.

FIG. 1E depicts an embodiment of memory block 140 in FIG. 1D. As depicted, memory block 140 includes a memory array 150, row decoder 152, and column decoder 154. Memory array 150 may include a contiguous group of non-volatile memory cells having contiguous word lines and bit lines. Memory array 150 may include one or more layers of non-volatile memory cells. Memory array 150 may include a two-dimensional memory array or a three-dimensional memory array.

Row decoder 152 decodes a row address and selects a particular word line in memory array 150 when appropriate (e.g., when reading or writing non-volatile memory cells in memory array 150). Column decoder 154 decodes a column address and selects one or more bit lines in memory array 150 to be electrically coupled to read/write circuits, such as read/write circuits 146 in FIG. 1D. In one embodiment, the number of word lines is 4K per memory layer, the number of bit lines is 1K per memory layer, and the number of memory layers is 4, providing a memory array 150 containing 16M non-volatile memory cells.

FIG. 1F depicts an embodiment of a memory bay 134. Memory bay 134 is an alternative example implementation for memory bay 130 of FIG. 1D. In some embodiments, row decoders, column decoders, and read/write circuits may be split or shared between memory arrays. As depicted, row decoder 152b is shared between memory arrays 150a and 150b because row decoder 152b controls word lines in both memory arrays 150a and 150b (i.e., the word lines driven by row decoder 152b are shared).

Row decoders 152a and 152b may be split such that even word lines in memory array 150a are driven by row decoder 152a and odd word lines in memory array 150a are driven by row decoder 152b. Row decoders 152c and 152b may be split such that even word lines in memory array 150b are driven by row decoder 152c and odd word lines in memory array 150b are driven by row decoder 152b.

Column decoders 154a and 154b may be split such that even bit lines in memory array 150a are controlled by column decoder 154b and odd bit lines in memory array 150a are driven by column decoder 154a. Column decoders 154c and 154d may be split such that even bit lines in memory array 150b are controlled by column decoder 154d and odd bit lines in memory array 150b are driven by column decoder 154c.

The selected bit lines controlled by column decoder 154a and column decoder 154c may be electrically coupled to read/write circuits 146a. The selected bit lines controlled by column decoder 154b and column decoder 154d may be electrically coupled to read/write circuits 146b. Splitting the read/write circuits into read/write circuits 146a and 146b when the column decoders are split may allow for a more efficient layout of the memory bay.

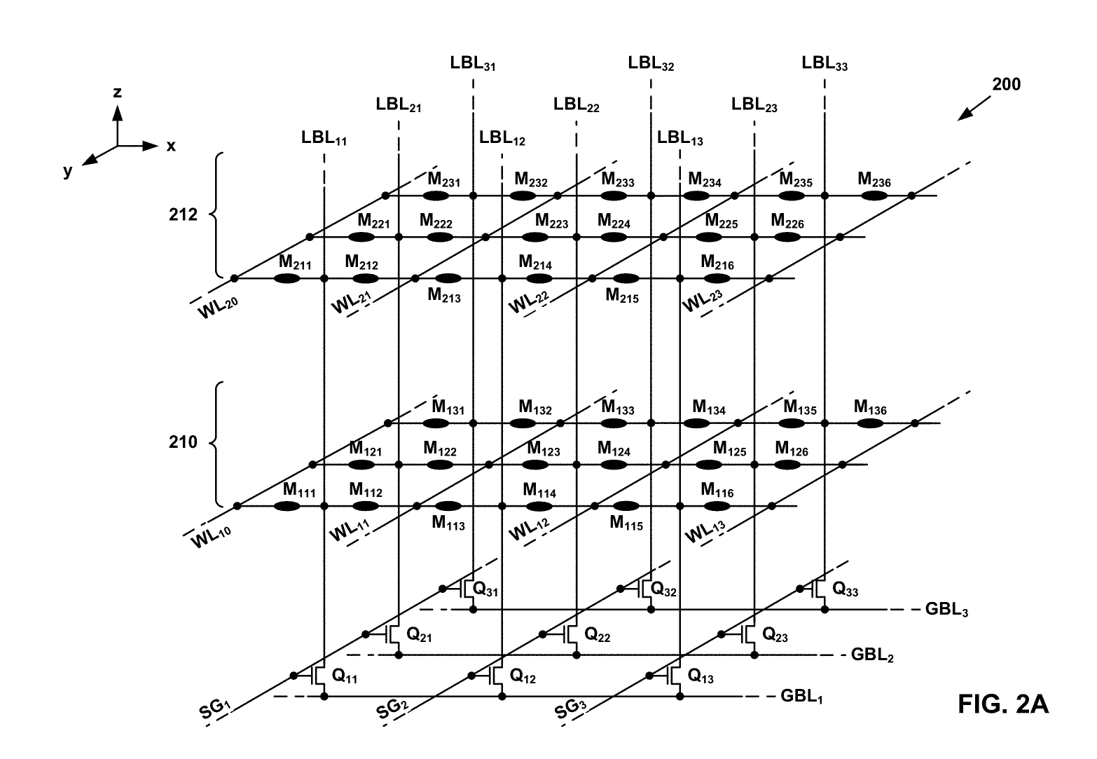

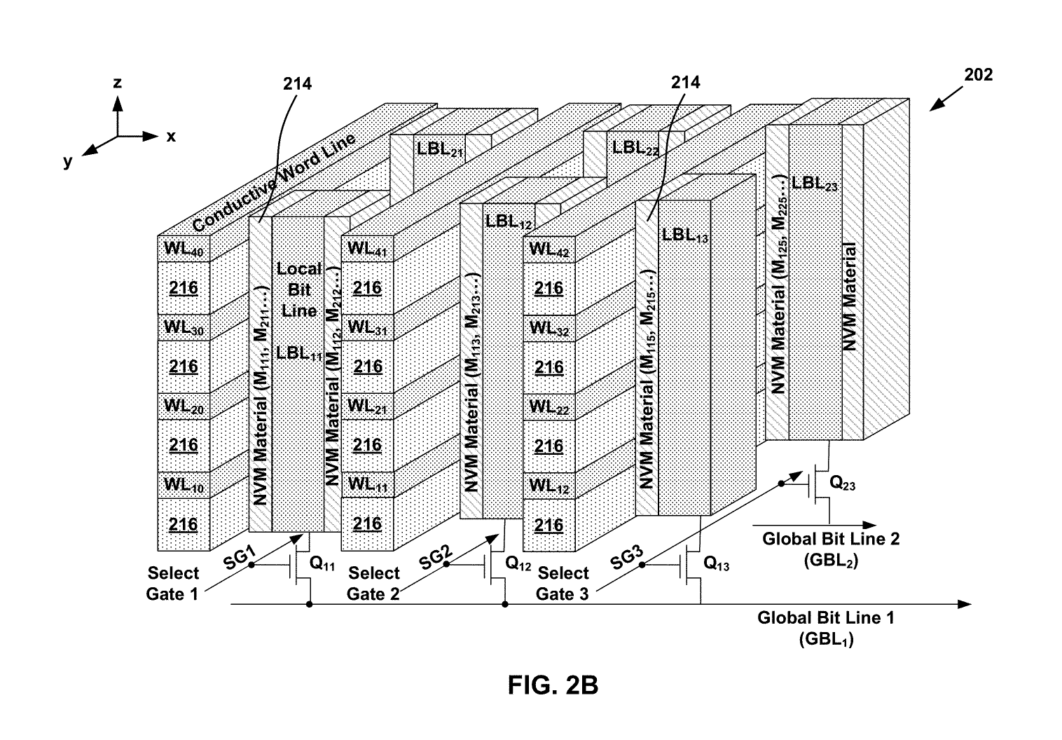

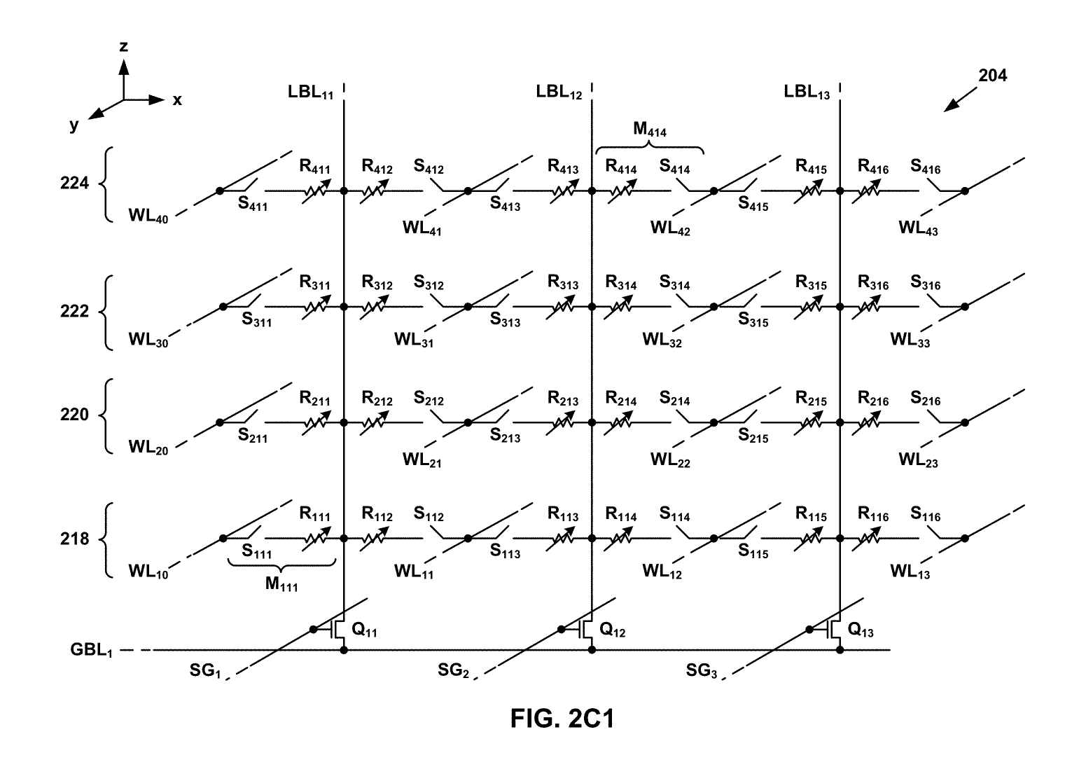

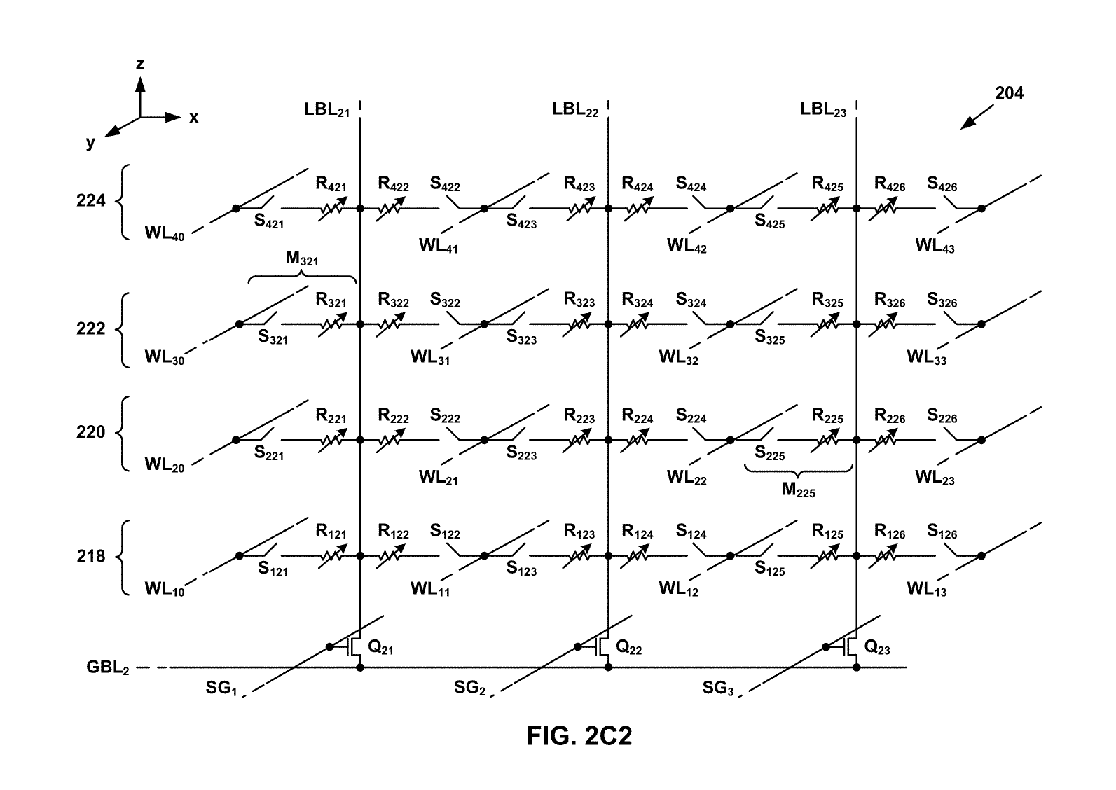

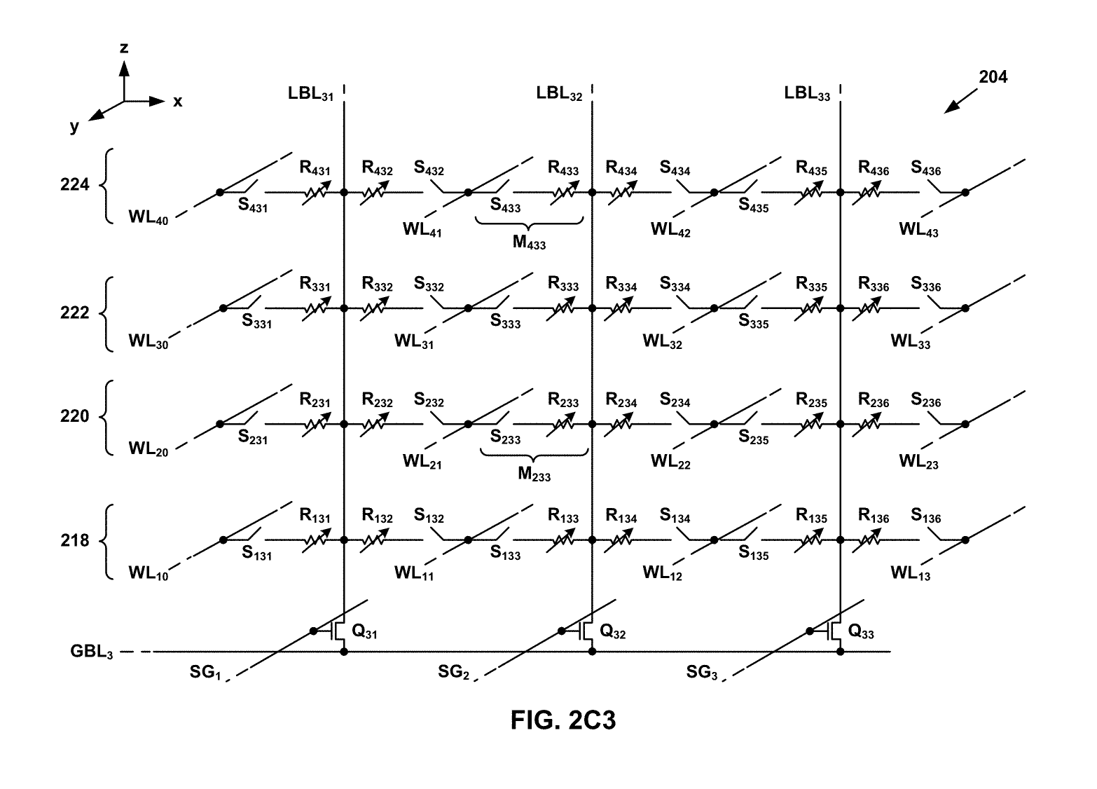

FIG. 2A depicts one embodiment of a portion of a monolithic three-dimensional memory array 200 that includes a first memory level 210, and a second memory level 212 positioned above first memory level 210. Memory array 200 is one example of an implementation for memory array 150 of FIG. 1E. Local bit lines LBL₁₁-LBL₃₃ are arranged in a first direction (e.g., a vertical or z-direction) and word lines WL₁₀-WL₂₃ are arranged in a second direction (e.g., an x-direction) perpendicular to the first direction. This arrangement of vertical bit lines in a monolithic three-dimensional memory array is one embodiment of a vertical bit line memory array.

As depicted, disposed between the intersection of each local bit line and each word line is a particular non-volatile memory cell (e.g., non-volatile memory cell M₁₁₁ is disposed between local bit line LBL₁₁ and word line WL₁₀). The particular non-volatile memory cell may include a floating gate memory element, a charge trap memory element (e.g., using a silicon nitride material), a reversible resistance-switching memory element, or other similar device. The global bit lines GBL₁-GBL₃ are arranged in a third direction (e.g., a y-direction) that is perpendicular to both the first direction and the second direction.

Each local bit line LBL₁₁-LBL₃₃ has an associated bit line select transistor Q₁₁-Q₃₃, respectively. Bit line select transistors Q₁₁-Q₃₃ may be field effect transistors, such as shown, or may be any other transistors. As depicted, bit line select transistors Q11-Q31 are associated with local bit lines LBL₁₁-LBL₃₁, respectively, and may be used to connect local bit lines LBL₁₁-LBL₃₁ to global bit lines GBL₁-GBL₃, respectively, using row select line SG₁. In particular, each of bit line select transistors Q₁₁-Q₃₁ has a first terminal (e.g., a drain/source terminal) coupled to a corresponding one of local bit lines LBL₁₁-LBL₃₃, respectively, a second terminal (e.g., a source/drain terminal) coupled to a corresponding one of global bit lines GBL₁-GBL₃, respectively, and a third terminal (e.g., a gate terminal) coupled to row select line SG₃.

Similarly, bit line select transistors Q₁₂-Q₃₂ are associated with local bit lines LBL₁₂-LBL₃₂, respectively, and may be used to connect local bit lines LBL₁₂-LBL₃₂ to global bit lines GBL₁-GBL₃, respectively, using row select line SG₂. In particular, each of bit line select transistors Q₁₂-Q₃₂ has a first terminal (e.g., a drain/source terminal) coupled to a corresponding one of local bit lines LBL₁₂-LBL₃₂, respectively, a second terminal (e.g., a source/drain terminal) coupled to a corresponding one of global bit lines GBL₁-GBL₃, respectively, and a third terminal (e.g., a gate terminal) coupled to row select line SG₂.

Likewise, bit line select transistors Q₁₃-Q₃₃ are associated with local bit lines LBL₁₃-LBL₃₃, respectively, and may be used to connect local bit lines LBL₁₃-LBL₃₃ to global bit lines GBL₁-GBL₃, respectively, using row select line SG₃. In particular, each of bit line select transistors Q₁₃-Q₃₃ has a first terminal (e.g., a drain/source terminal) coupled to a corresponding one of local bit lines LBL₁₃-LBL₃₃, respectively, a second terminal (e.g., a source/drain terminal) coupled to a corresponding one of global bit lines GBL₁-GBL₃, respectively, and a third terminal (e.g., a gate terminal) coupled to row select line SG₃.

Because a single bit line select transistor is associated with a corresponding local bit line, the voltage of a particular global bit line may be applied to a corresponding local bit line. Therefore, when a first set of local bit lines (e.g., LBL₁₁-LBL₃₃) is biased to global bit lines GBL₁-GBL₃, the other local bit lines (e.g., LBL₁₂-LBL₃₂ and LBL₁₃-LBL₃₃) must either also be driven to the same global bit lines GBL₁-GBL₃ or be floated.

In an embodiment, during a memory operation, all local bit lines within the memory array are first biased to an unselected bit line voltage by connecting each of the global bit lines to one or more local bit lines. After the local bit lines are biased to the unselected bit line voltage, then only a first set of local bit lines LBL₁₁-LBL₃₁ are biased to one or more selected bit line voltages via the global bit lines GBL₁-GBL₃, while the other local bit lines (e.g., LBL₁₂-LBL₃₂ and LBL₁₃-LBL₃₃) are floated. The one or more selected bit line voltages may correspond with, for example, one or more read voltages during a read operation or one or more programming voltages during a programming operation.

In an embodiment, a vertical bit line memory array, such as memory array 200, includes a greater number of non-volatile memory cells along the word lines as compared with the number of non-volatile memory cells along the vertical bit lines (e.g., the number of non-volatile memory cells along a word line may be more than 10 times the number of non-volatile memory cells along a bit line). In one example, the number of non-volatile memory cells along each bit line may be 16 or 32, whereas the number of non-volatile memory cells along each word line may be 2048 or more than 4096. Other numbers of non-volatile memory cells along each bit line and along each word line may be used.

In an embodiment of a read operation, the data stored in a selected non-volatile memory cell (e.g., non-volatile memory cell M₁₁₁) may be read by biasing the word line connected to the selected non-volatile memory cell (e.g., selected word line WL₁₀) to a selected word line voltage in read mode (e.g., 0V). The local bit line (e.g., LBL₁₁) coupled to the selected non-volatile memory cell (M₁₁₁) is biased to a selected bit line voltage in read mode (e.g., 1 V) via the associated bit line select transistor (e.g., Q₁₁) coupled to the selected local bit line (LBL₁₁), and the global bit line (e.g., GBL₁) coupled to the bit line select transistor (Q₁₁). A sense amplifier may then be coupled to the selected local bit line (LBL₁₁) to determine a read current I_{READ} of the selected non-volatile memory cell (M₁₁₁). The read current I_{READ} is conducted by the bit line select transistor Q₁₁, and may be between about 100 nA and about 500 nA, although other read currents may be used.

In an embodiment of a write operation, data may be written to a selected non-volatile memory cell (e.g., non-volatile memory cell M₂₂₁) by biasing the word line connected to the selected non-volatile memory cell (e.g., WL₂₀) to a selected word line voltage in write mode (e.g., 5V). The local bit line (e.g., LBL₂₁) coupled to the selected non-volatile memory cell (M₂₂₁) is biased to a selected bit line voltage in write mode (e.g., 0 V) via the associated bit line select transistor (e.g., Q₂₁) coupled to the selected local bit line (LBL₂₁), and the global bit line (e.g., GBL₂) coupled to the bit line select transistor (Q₂₁). During a write operation, a programming current I_{PGRM} is conducted by the associated bit line select transistor Q₂₁, and may be between about 3 uA and about 6 uA, although other programming currents may be used.

FIG. 2B depicts an embodiment of a portion of a monolithic three-dimensional memory array 202 that includes vertical strips of a non-volatile memory material. The portion of monolithic three-dimensional memory array 202 depicted in FIG. 2B may include an implementation for a portion of the monolithic three-dimensional memory array 200 depicted in FIG. 2A.

Monolithic three-dimensional memory array 202 includes word lines WL₁₀, WL₁₁, WL₁₂, . . . , WL₄₂ that are formed in a first direction (e.g., an x-direction), vertical bit lines LBL₁₁, LBL₁₂, LBL₁₃, . . . , LBL₂₃ that are formed in a second direction perpendicular to the first direction (e.g., a z-direction), and vertical strips of non-volatile memory material 214 formed in the second direction (e.g., the z-direction). A spacer 216 made of a dielectric material (e.g., silicon dioxide, silicon nitride, or other dielectric material) is disposed between adjacent word lines WL₁₀, WL₁₁, WL₁₂, . . . , WL₄₂.

The vertical strip of the non-volatile memory material 214 may include, for example, a vertical oxide material, a vertical reversible resistance-switching memory material (e.g., a metal oxide layer such as nickel oxide, hafnium oxide, or other similar metal oxide material, a phase change material or other similar reversible resistance-switching memory material), or a vertical charge trapping material (e.g., a layer of silicon nitride). In an embodiment, the vertical strip of material 214 may include a single continuous layer of material that may be used by a plurality of non-volatile memory cells or devices.

In an embodiment, portions of the vertical strip of the non-volatile memory material 214b may include a part of a first non-volatile memory cell associated with the cross section between WL₁₂ and LBL₁₃ and a part of a second non-volatile memory cell associated with the cross section between WL₂₂ and LBL₁₃. In some cases, a vertical bit line, such as LBL₁₃, may include a vertical structure (e.g., a rectangular prism, a cylinder, or a pillar) and the non-volatile material may completely or partially surround the vertical structure (e.g., a conformal layer of phase change material surrounding the sides of the vertical structure).

As depicted, each of the vertical bit lines LBL₁₁, LBL₁₂, LBL13, . . . , LBL₂₃ may be connected to one of a set of global bit lines via an associated vertically-oriented bit line select transistor (e.g., Q₁₁, Q₁₂, Q₁₃, Q₂₃). Each vertically-oriented bit line select transistor may include a MOS device (e.g., an NMOS device) or a vertical thin-film transistor (TFT).

In an embodiment, each vertically-oriented bit line select transistor is a vertically-oriented pillar-shaped TFT coupled between an associated local bit line pillar and a global bit line. In an embodiment, the vertically-oriented bit line select transistors are formed in a pillar select layer formed above a CMOS substrate, and a memory layer that includes multiple layers of word lines and memory elements is formed above the pillar select layer.

FIGS. 2C1-2C3 depict an embodiment of a portion of a monolithic three-dimensional memory array 204 that includes a first memory level 218, a second memory level 220 positioned above first memory level 218, a third memory level 222 positioned above second memory level 220, and a fourth memory level 224 positioned above third memory level 222. Memory array 204 is one example of an implementation for memory array 150 of FIG. 1E.

As depicted, disposed between the intersection of each local bit line and each word line is a particular non-volatile memory cell. For example, non-volatile memory cell M₁₁₁ is disposed between local bit line LBL₁₁ and word line WL₁₀, non-volatile memory cell M₂₂₅ is disposed between local bit line LBL₂₃ and word line WL₂₂, and non-volatile memory cell M₄₃₃ is disposed between local bit line LBL₃₂ and word line WL₄₁.

In an embodiment, each non-volatile memory cell includes a reversible resistance-switching memory element coupled in series with an isolation element. For example, non-volatile memory cell M₄₁₄ includes reversible resistance-switching memory element R₄₁₄ coupled in series with isolation element S₄₁₄, non-volatile memory cell M₃₂₁ includes reversible resistance-switching memory element R₃₂₁ coupled in series with isolation element S₃₂₁, and non-volatile memory cell M₂₃₃ includes reversible resistance-switching memory element R₂₃₃ coupled in series with isolation element S₂₃₃.

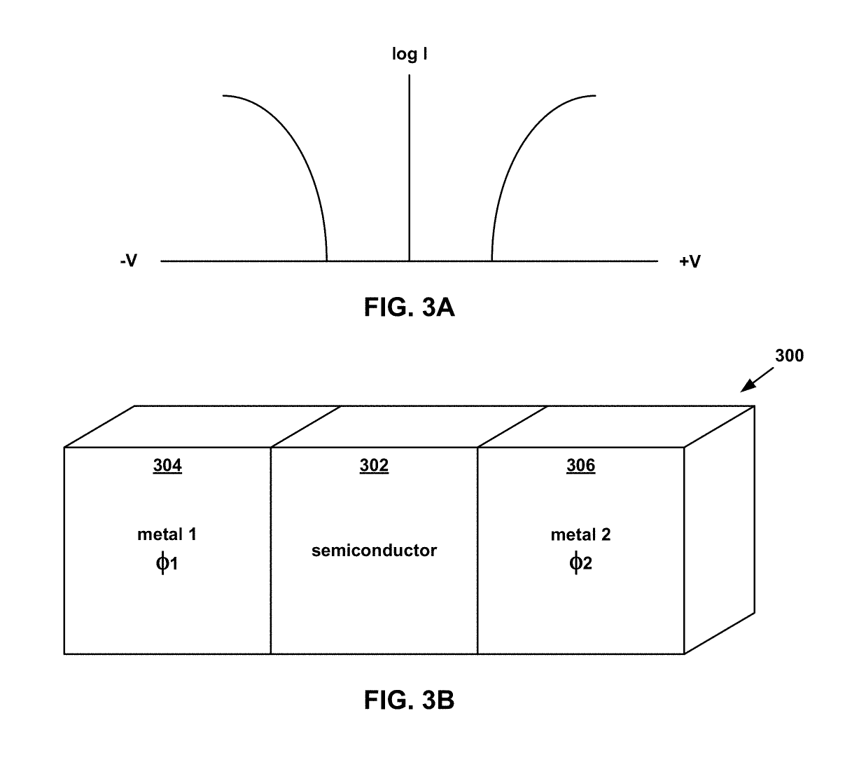

In an embodiment, each of isolation elements S₁₁₁-S₄₃₆ of monolithic three-dimensional memory array 204 exhibits an ON-state current density of greater than about 1-10 MA/cm², an OFF-state leakage current of less than about 10 nA, an ON/OFF current ratio of greater than about 500, a low-leakage voltage zone of between about 0 volts and about 1.2 volts. In addition, in an embodiment, each of isolation elements S₁₁₁-S₄₃₆ of monolithic three-dimensional memory array 204 exhibits bipolar operation, such as depicted in the current versus voltage diagram depicted in FIG. 3A.

FIG. 3B is a diagram of a perspective view of an embodiment of an isolation element 300. Isolation element 300 is one example of an implementation for isolation elements S₁₁₁-S₄₃₆ of FIG. 2C1-2C3. Isolation element 300 includes a first portion 302 disposed between a first electrode 304 and a second electrode 306. In an embodiment, first portion 302 is a semiconductor material, first electrode 304 includes a first metal, and second electrode 306 includes a second metal. In this regard, isolation element 300 is a metal-semiconductor-metal isolation element. Without wanting to be bound by any particular theory, it is believed that isolation element 300 exhibits the bipolar current-voltage characteristic of two back-to-back Schottky diodes.

In an embodiment, first portion 302 is amorphous silicon (a-Si), which is a non-crystalline form of silicon in which the silicon atoms form a continuous random network. Alternatively, first portion 302 may be polycrystalline silicon. Other semiconductor materials may be used for first portion 302, such as silicon germanium, germanium or other similar semiconductor materials. In embodiments, first portion 302 may be a doped or an undoped semiconductor material, and may be amorphous or polycrystalline.

In an embodiment, first electrode 304 includes a first metal having a first work function φ1, and second electrode 306 includes a second metal having second work function φ2, with first work function φ1 not equal to second work function φ2. In embodiments, a magnitude of a difference between first work function φ1 and second work function φ2 is greater than a threshold Δφ:

|φ1−φ2|>Δφ

where Δφ us about 0.1 eV

In this regard, first electrode 304 and second electrode 306 of isolation element 300 have asymmetric work functions. Without wanting to be bound by any particular theory, it is believed that using a first electrode 304 and a second electrode 306 having asymmetric work functions may increase the ON/OFF current ratio of isolation element 300. Without wanting to be bound by any particular theory, it is believed that the increase in the ON/OFF current ratio of isolation element 300 is contrary to what would be expected as a result of introducing such asymmetry into isolation element 300.

In an embodiment, first work function φ1 is greater than about 4.8 eV and second work function φ2 is less than about 4.4 eV. For example, first electrode 304 may include one or more of ruthenium, ruthenium oxide, rhodium, rhenium, platinum, iridium or other similar materials, and second electrode 306 may include one or more of titanium nitride, tantalum, tantalum nitride, tungsten nitride, tin oxide, indium tin oxide or other similar materials.

In other embodiments, first work function φ1 may be less than second work function φ2. For example, first electrode 304 may include one or more of titanium nitride, tantalum, tantalum nitride, tungsten nitride, tin oxide, indium tin oxide or other similar materials, and second electrode 306 may include one or more of ruthenium, ruthenium oxide, rhodium, rhenium, platinum, iridium or other similar materials.

Referring again to FIGS. 2C1-2C3, isolation elements S₁₁₁-S₄₃₆ are each coupled between one of word lines WL₁₀-WL₄₃ and a corresponding one of reversible resistance-switching memory elements R₁₁₁-R₄₃₆, respectively. Accordingly, in an embodiment, each of isolation elements S₁₁₁-S₄₃₆ may include one of isolation elements 300 of FIG. 3B, with word lines WL₁₀-WL₄₃ forming a first electrode 304 of each isolation element S₁₁₁-S₄₃₆.

The monolithic three-dimensional memory array 204 illustrated in FIGS. 2C1-2C3 includes vertical bit lines and horizontal word lines. The technology described above also may be used in other monolithic three-dimensional memory array configurations. For example, a cross-point memory array may include non-volatile memory cells each having a reversible resistance-switching memory element coupled in series with an isolation element such as isolation element 300 described above and illustrated in FIG. 3B.

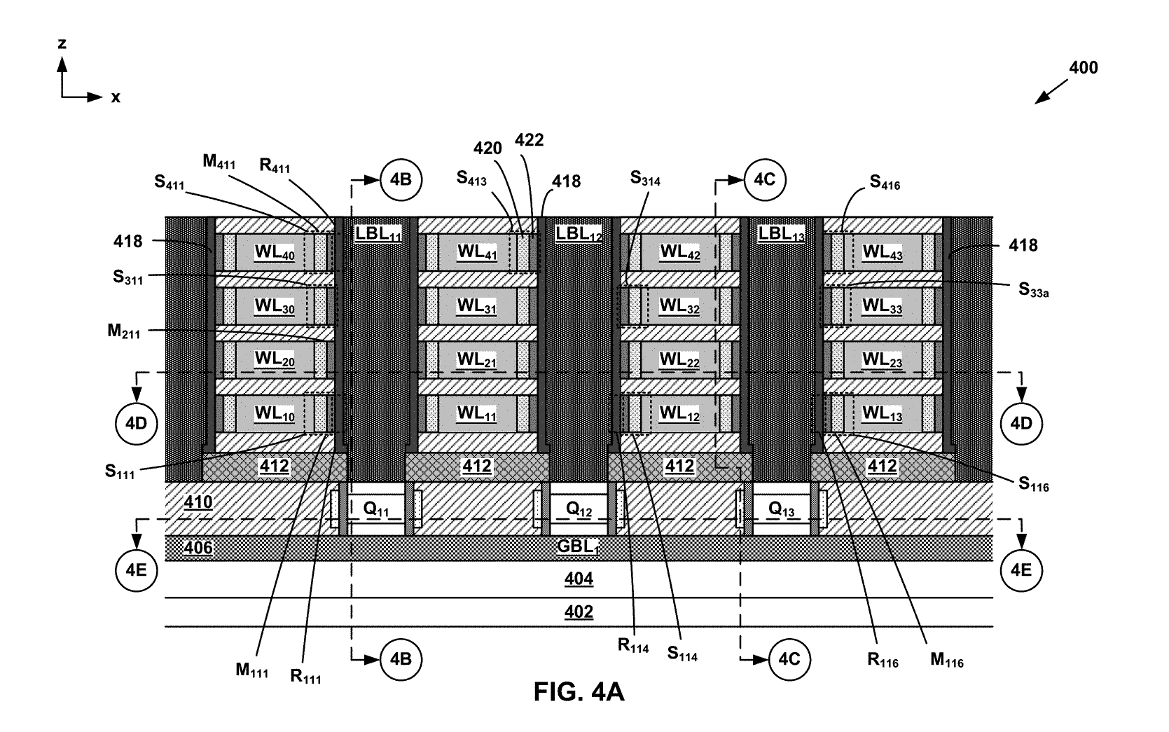

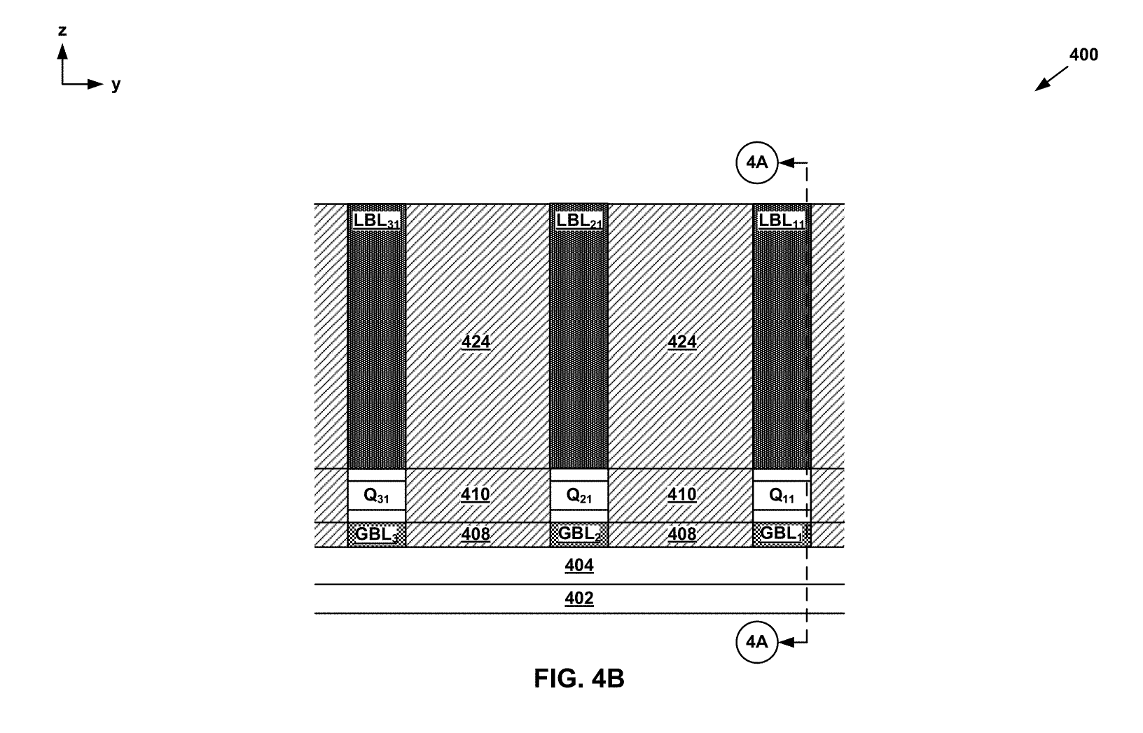

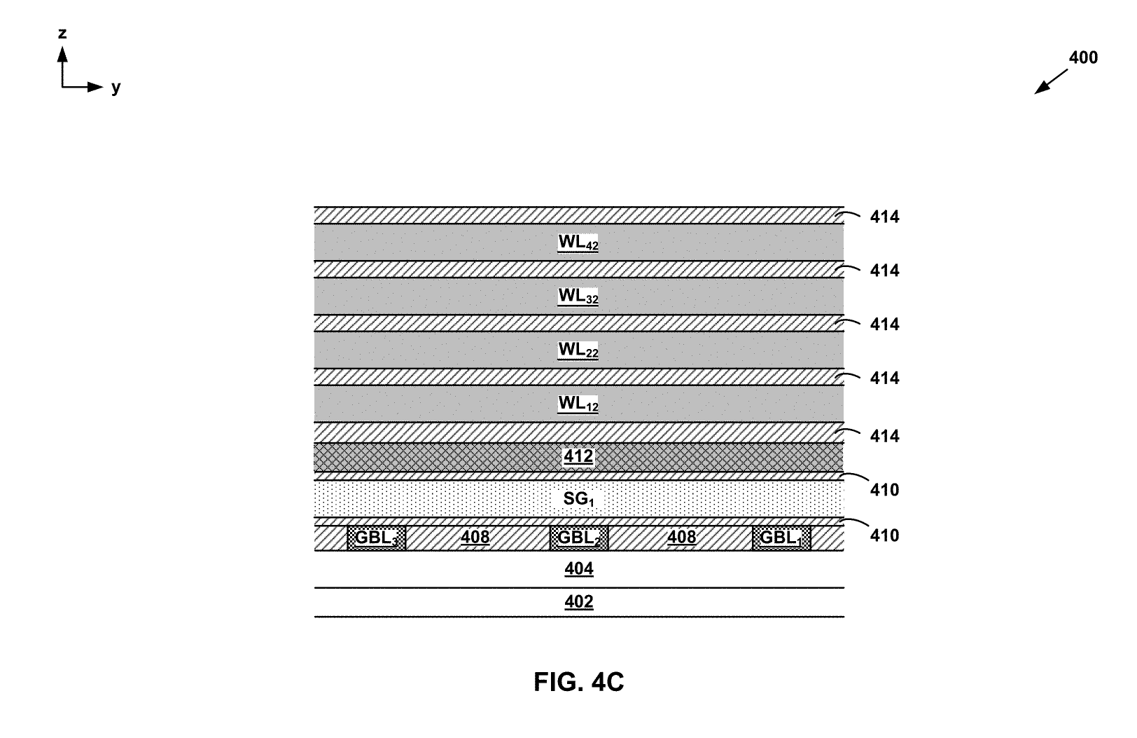

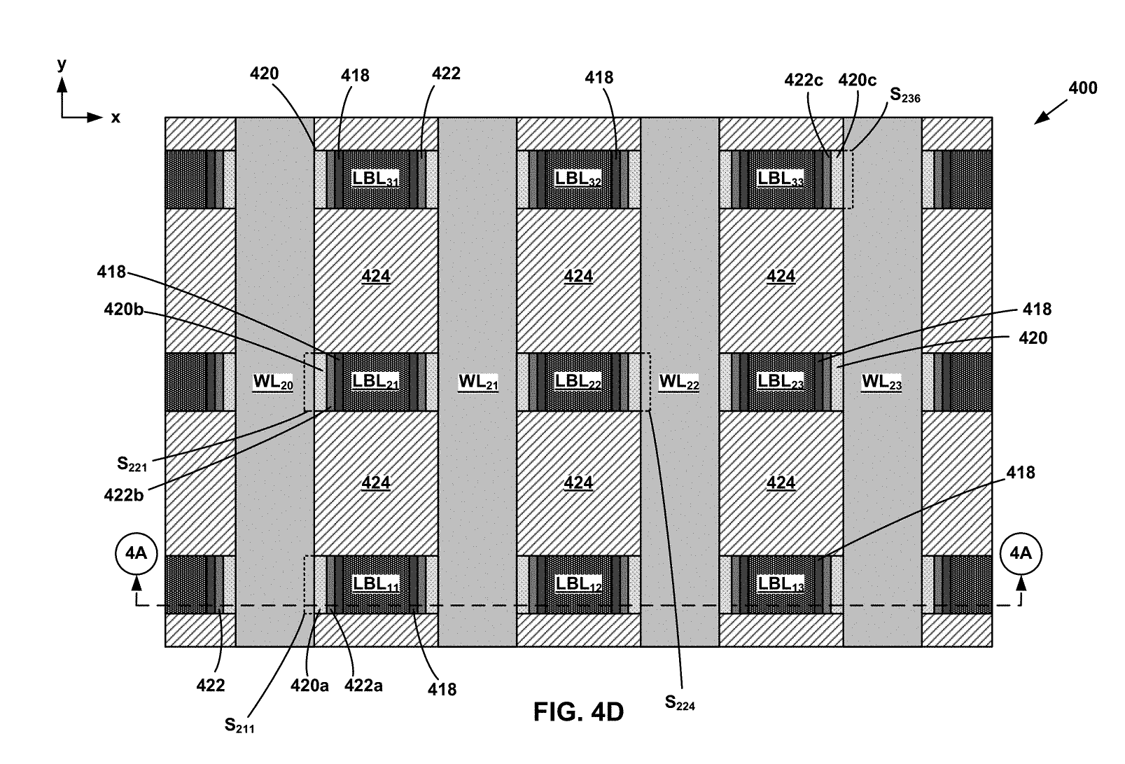

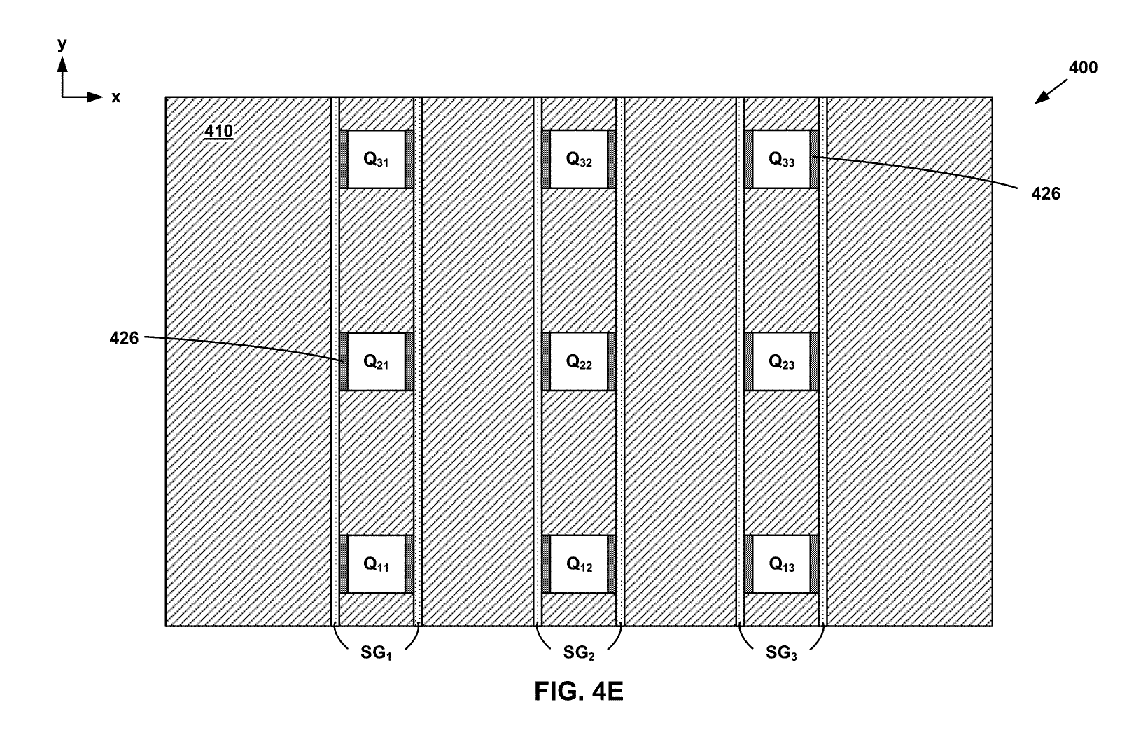

FIGS. 4A-4E depict various views of an embodiment of a portion of a monolithic three-dimensional memory array 400 that includes vertical strips of a non-volatile memory material. The physical structure depicted in FIGS. 4A-4E may include one implementation for a portion of the monolithic three-dimensional memory array depicted in FIG. 2A.

Monolithic three-dimensional memory array 400 includes vertical bit lines LBL₁₁-LBL₃₃ arranged in a first direction (e.g., a z-direction), word lines WL₁₀, WL₁₁ . . . , WL₄₃ arranged in a second direction (e.g., an x-direction) perpendicular to the first direction, row select lines SG₁, SG₂, SG₃ arranged in the second direction, and global bit lines GBL₁, GBL₂, GBL₃ arranged in a third direction (e.g., a y-direction) perpendicular to the first and second directions. Vertical bit lines LBL₁₁-LBL₃₃ are disposed above global bit lines GBL₁, GBL₂, GBL₃, which each have a long axis in the second (e.g., x-direction). Person of ordinary skill in the art will understand that monolithic three-dimensional memory arrays, such as monolithic three-dimensional memory array 400 may include more or fewer than twenty-four word lines, three row select lines, three global bit lines, and nine vertical bit lines.

In an embodiment, global bit lines GBL₁, GBL₂, GBL₃ are disposed above a substrate 402, such as a silicon, germanium, silicon-germanium, undoped, doped, bulk, silicon-on-insulator (“SOI”) or other substrate with or without additional circuitry. In an embodiment, an isolation layer 404, such as a layer of silicon dioxide, silicon nitride, silicon oxynitride or any other suitable insulating layer, is formed above substrate 402. In an embodiment, global bit lines GBL₁, GBL₂, GBL₃ are formed of a conductive material 406, such as tungsten or another appropriate metal, heavily doped semiconductor material, a conductive silicide, a conductive silicide-germanide, a conductive germanide, or the like deposited by any suitable method (e.g., CVD, PVD, etc.).

In an embodiment, a first dielectric material layer 408 (e.g., silicon dioxide) and a second dielectric material layer 410 (e.g., silicon dioxide) are formed above isolation layer 404. Global bit lines GBL₁, GBL₂, GBL₃ are disposed above isolation layer 404 and are separated from one another by first dielectric material layer 408. Row select lines SG₄, SG₂, SG₃ are disposed above global bit lines GBL₁, GBL₂, GBL₃. A first etch stop layer 412 (e.g., silicon nitride) is disposed above second dielectric material layer 410. A stack of word lines WL₁₀, WL₁₁, . . . , WL₄₃ is disposed above first etch stop layer 412, with a third dielectric material layer 414 (e.g., silicon dioxide) separating adjacent word lines.

In an embodiment, vertical strips of a non-volatile memory material 418 are disposed between vertical bit lines LBL₁₁-LBL₃₃ and word lines WL₁₀, WL₁₁, . . . , WL₄₃. Vertical strips of non-volatile memory material 418 may be formed in the first direction (e.g., the z-direction). A vertical strip of non-volatile memory material 418 may include, for example, a vertical oxide layer, a vertical reversible resistance-switching material (e.g., a metal oxide layer such as nickel oxide, hafnium oxide, or other similar metal oxide material, a phase change material or other similar reversible resistance-switching material), a vertical charge trapping layer (e.g., a layer of silicon nitride), or other non-volatile memory material.

A vertical strip of non-volatile memory material 418 may include a single continuous layer of material that may be used by a plurality of non-volatile memory cells or devices. For simplicity, vertical strip of the non-volatile memory material 418 will be referred to in the remaining discussion as reversible resistance-switching memory material 418.

In an embodiment, strips of a semiconductor material 420 are disposed between word lines WL₁₀, WL₄₄, . . . , WL₄₃ and strips of a metal material 422. Strips of semiconductor material 420 and strips of a metal material 422 may be formed in the third direction (e.g., the y-direction). Each strip of semiconductor material 420 may include, for example, a layer of silicon, silicon germanium, germanium or other similar semiconductor material. Semiconductor material 420 may be an amorphous or a polycrystalline semiconductor material. Each strip of metal material 422 may include, for example, a layer of one or more of titanium nitride, tantalum, tantalum nitride, tin oxide or other similar metal material.

Vertical bit lines LBL₁₁-LBL₃₃ are formed of a conductive material (e.g., a highly doped polysilicon material) and are separated from one another by a fourth dielectric material layer 424 (e.g., silicon dioxide). Vertical bit lines LBL₁₁-LBL₃₃ also may include an adhesion layer (e.g., titanium nitride) (not shown) disposed on an outer surface of each vertical bit line LBL₁₁-LBL₃₃. In some embodiments, each of a vertical bit lines LBL₁₁-LBL₃₃ includes a vertical structure (e.g., a rectangular prism, a cylinder, or a pillar), and the vertical strip of reversible resistance-switching memory material 418 may completely or partially surround the vertical structure (e.g., a conformal layer of reversible resistance-switching material surrounding the sides of the vertical structure).

A non-volatile memory cell is disposed between the intersection of each vertical bit line and each word line. For example, a non-volatile memory cell M₁₁₁ is disposed between vertical bit line LBL₁₁ and word line WL₁₀, a non-volatile memory cell M₁₁₆ is disposed between vertical bit line LBL₁₃ and word line WL₁₃, a non-volatile memory cell M₄₁₁ is disposed between vertical bit line LBL₁₁ and word line WL₄₀, and so on. In an embodiment, monolithic three-dimensional memory array 400 includes seventy-two non-volatile memory cells M₁₁₁, M₁₁₂, . . . , M₄₃₆. Persons of ordinary skill in the art will understand that monolithic three-dimensional memory arrays may include more or fewer than seventy-two non-volatile memory cells.

In an embodiment, portions of the vertical strip of reversible resistance-switching material 418 may include a part of non-volatile memory cell M₁₁₁ associated with the cross section between word line WL₁₀ and LBL₁₁, and a part of non-volatile memory cell M₂₁₁ associated with the cross section between word line WL₂₀ and LBL₁₁, and so on.

In an embodiment, each of non-volatile memory cells M₁₁₁, M₁₁₂, . . . , M₄₃₆ includes a corresponding reversible resistance-switching memory element R₁₁₁, R₁₁₂, . . . , R₄₃₆, respectively, coupled in series with a corresponding isolation element S₁₁₁, S₁₁₂, . . . , S₄₃₆, respectively. For example, non-volatile memory cell M₁₁₁ includes reversible resistance-switching memory element R₁₁₁ coupled in series with isolation element S₁₁₁, non-volatile memory cell M₄₁₁ includes reversible resistance-switching memory element R₄₁₁ coupled in series with isolation element S₄₁₁, non-volatile memory cell M₁₁₆ includes reversible resistance-switching memory element R₁₁₆ coupled in series with isolation element S₁₁₆, and so on.

In an embodiment, each of isolation elements S₁₁₁, S₁₁₂, . . . , S₄₃₆, is a metal-semiconductor-metal isolation element, such as isolation element 300 of FIG. 3B, and includes a portion of a word line, a strip of semiconductor material 420, and a strip of metal material 422. For example, as depicted in FIG. 4D, isolation element S₂₁₁ includes a portion of word line WL₂₀ adjacent vertical bit line LBL₁₁, a strip of metal material 422a adjacent vertical bit line LBL₁₁, and a strip of semiconductor material 420a disposed between word line WL₂₀ and strip of metal material 422a.

Likewise, isolation element S₂₂₁ includes a portion of word line WL₂₀ adjacent vertical bit line LBL₂₁, a strip of metal material 422b adjacent vertical bit line LBL₂₁, and a strip of semiconductor material 420b disposed between word line WL₂₀ and strip of metal material 422b.

Similarly, isolation element S₂₃₆ includes a portion of word line WL₂₃ adjacent vertical bit line LBL₃₃, a strip of metal material 422c adjacent vertical bit line LBL₃₃, and a strip of semiconductor material 420c disposed between word line WL₂₃ and strip of metal material 422c.

In an embodiment, each of word lines WL₁₀, WL₁₁, . . . , WL₄₃ includes a first metal having a first work function φ1, and each strip of metal material 422 includes a second metal having a second work function φ2, with first work function φ1 different from second work function φ2. In an embodiment, first work function φ1 is greater than second work function φ2. In another embodiment, first work function φ1 is less than second work function φ2.

In an embodiment, first work function φ1 is greater than about 4.8 eV and second work function φ2 is less than about 4.4 eV. In an embodiment, each of word lines WL₁₀, WL₁₁, . . . , WL₄₃ includes one or more of ruthenium, ruthenium oxide, rhodium, rhenium, platinum, iridium or other similar materials, and each strip of metal material 422 includes one or more of titanium nitride, tantalum, tantalum nitride, tin oxide or other similar materials.

Alternatively, first work function φ1 may be less than second work function φ2. For example, in another embodiment, each of word lines WL₁₀, WL₁₁, . . . , WL₄₃ includes one or more of titanium nitride, tantalum, tantalum nitride, tin oxide or other similar materials, and each strip of metal material 422 includes one or more of ruthenium, ruthenium oxide, rhodium, rhenium, platinum, iridium or other similar materials.

Each of non-volatile memory cells M₁₁₁, M₁₁₂, . . . , M₄₃₆ may include a floating gate device, a charge trap device (e.g., using a silicon nitride material), a resistive change memory device, or other type of memory device. Vertically-oriented bit line select transistors Q₁₁-Q₃₃ may be used to select a corresponding one of vertical bit lines LBL₁₁-LBL₃₃. Vertically-oriented bit line select transistors Q₁₁-Q₃₃ may be field effect transistors, although other transistors types may be used.

Each of vertically-oriented bit line select transistors Q₁₁-Q₃₃ has a first terminal (e.g., a drain/source terminal), a second terminal (e.g., a source/drain terminal), a first control terminal (e.g., a first gate terminal) and a second control terminal (e.g., a second gate terminal). The first gate terminal and the second gate terminal may be disposed on opposite sides of the vertically-oriented bit line select transistor. The first gate terminal may be used to selectively induce a first conductive channel between the first terminal and the second terminal of the transistor, and the second gate terminal may be used to selectively induce a second conductive channel between the first terminal and the second terminal of the transistor.

In an embodiment, the first gate terminal and the second gate terminal are coupled together to form a single control terminal that may be used to collectively turn ON and OFF the vertically-oriented bit line select transistor. Thus, the first gate terminal and the second gate terminal of each of vertically-oriented bit line select transistors Q₁₁-Q₃₃ may be used to select a corresponding one of vertical bit lines LBL₁₁-LBL₁₂, . . . , LBL₃₃. Without wanting to be bound by any particular theory, for each of vertically-oriented bit line select transistors Q₁₁-Q₃₃, it is believed that the current drive capability of the transistor may be increased by using both the first gate terminal and the second gate terminal to turn ON the transistor. For simplicity, the first and second gate terminal of each of select transistors Q₁₁-Q₃₃ will be referred to as a single gate terminal.

Referring to FIGS. 4A and 4E, vertically-oriented bit line select transistors Q₁₁, Q₁₂, Q₁₃ are used to selectively connect/disconnect vertical bit lines LBL₁₁, LBL₁₂, LBL₁₃ to/from global bit line GBL₁ using row select lines SG₁, SG₂, SG₃, respectively. In particular, each of vertically-oriented bit line select transistors Q₁₁, Q₁₂, Q₁₃ has a first terminal (e.g., a drain./source terminal) coupled to a corresponding one of vertical bit lines LBL₁₁, LBL₁₂, LBL₁₃, respectively, a second terminal (e.g., a source/drain terminal) coupled to global bit line GBL₁, and a control terminal (e.g., a gate terminal) coupled to row select line SG₁, SG₂, SG₃, respectively.

Row select lines SG₁, SG₂, SG₃ are used to turn ON/OFF vertically-oriented bit line select transistors Q₁₁, Q₁₂, Q₁₃, respectively, to connect/disconnect vertical bit lines LBL₁₁, LBL₁₂, LBL₁₃, respectively, to/from global bit line GBL₁. A gate dielectric material layer 426 (e.g., silicon dioxide) is disposed between row select lines SG₁, SG₂, SG₃ and vertically-oriented bit line select transistors Q₁₁, Q₁₂, Q₁₃.

Likewise, vertically-oriented bit line select transistors Q₁₁, Q₂₁, . . . , Q₃₃ are used to selectively connect/disconnect vertical bit lines LBL₁₁, LBL₂₁, LBL₃₁ to global bit lines GBL₁, GBL₂, GBL₃, respectively, using row select line SG₁. In particular, each of vertically-oriented bit line select transistors Q₁₁, Q₂₁, Q₃₁ has a first terminal (e.g., a drain/source terminal) coupled to a corresponding one of vertical bit lines LBL₁₁, LBL₂₁, LBL₃₁, respectively, a second terminal (e.g., a source/drain terminal) coupled to a corresponding one of global bit lines GBL₁, GBL₂, GBL₃, respectively, and a control terminal (e.g., a gate terminal) coupled to row select line SG₁. Row select line SG₁ is used to turn ON/OFF vertically-oriented bit line select transistors Q₁₁, Q₂₁, Q₃₁ to connect/disconnect vertical bit lines LBL₁₁, LBL₂₁, LBL₃₁, respectively, to/from global bit lines GBL₁, GBL₂, GBL₃, respectively.

Similarly, vertically-oriented bit line select transistors Q₁₃, Q₂₃, Q₃₃ are used to selectively connect/disconnect vertical bit lines LBL₁₃, LBL₂₃, LBL₃₃ to/from global bit lines GBL₁, GBL₂, GBL₃, respectively, using row select line SG₃. In particular, each of vertically-oriented bit line select transistors Q₁₃, Q₂₃, Q₃₃ has a first terminal (e.g., a drain/source terminal) coupled to a corresponding one of vertical bit lines LBL₁₃, LBL₂₃, LBL₃₃, respectively, a second terminal (e.g., a source/drain terminal) coupled to a corresponding one of global bit lines GBL₁, GBL₂, GBL₃, respectively, and a control terminal (e.g., a gate terminal) coupled to row select line SG₃. Row select line SG₃ is used to turn ON/OFF vertically-oriented bit line select transistors Q₁₃, Q₂₃, Q₃₃ to connect/disconnect vertical bit lines LBL₁₃, LBL₂₃, LBL₃₃, respectively, to/from global bit lines GBL₁, GBL₂, GBL₃, respectively.

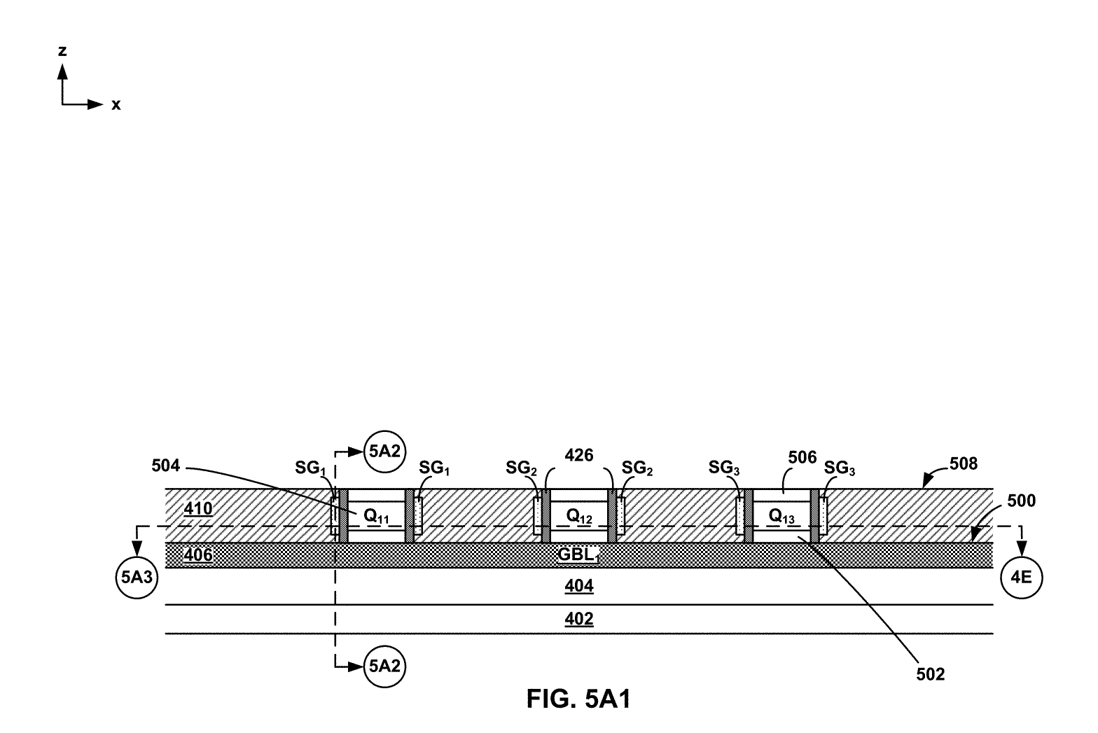

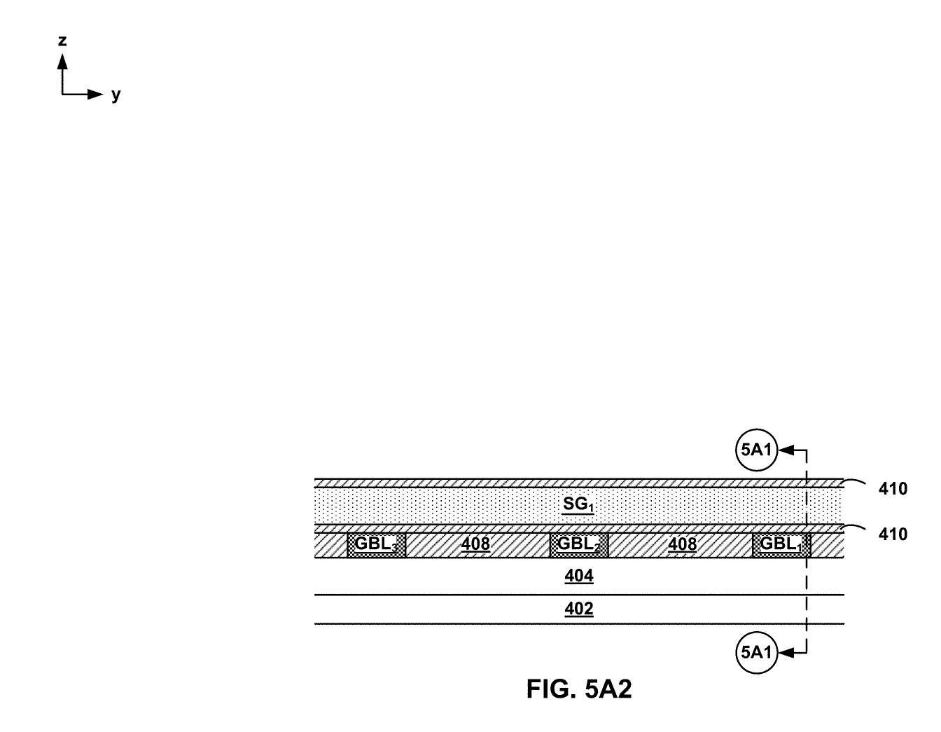

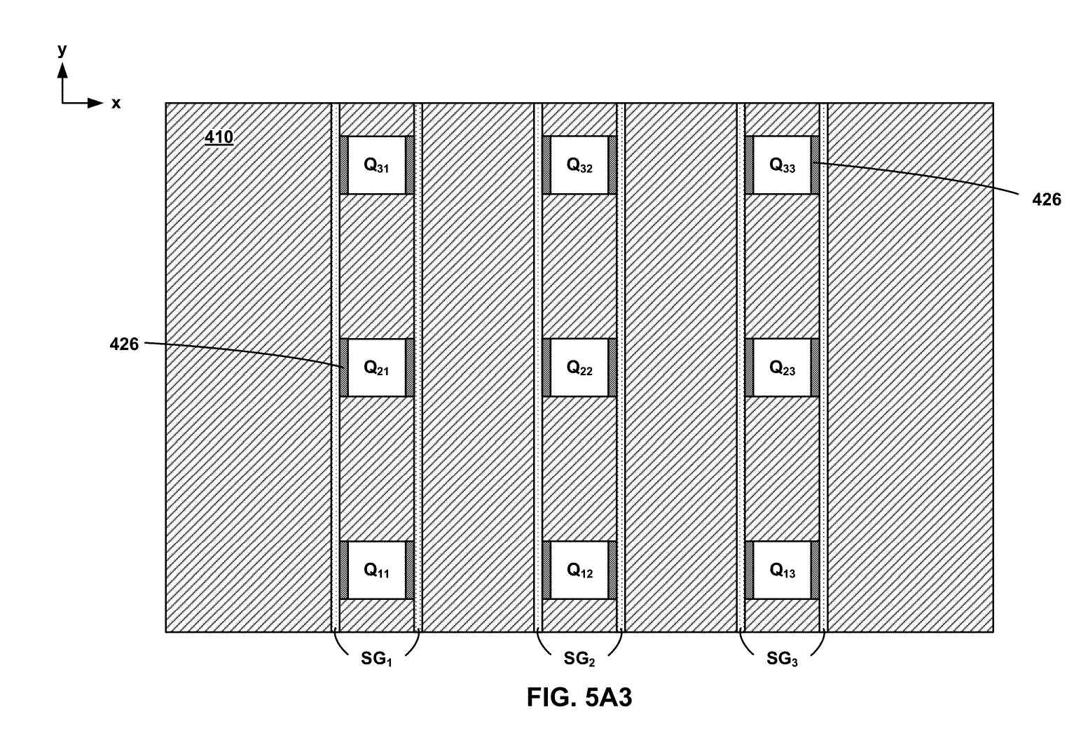

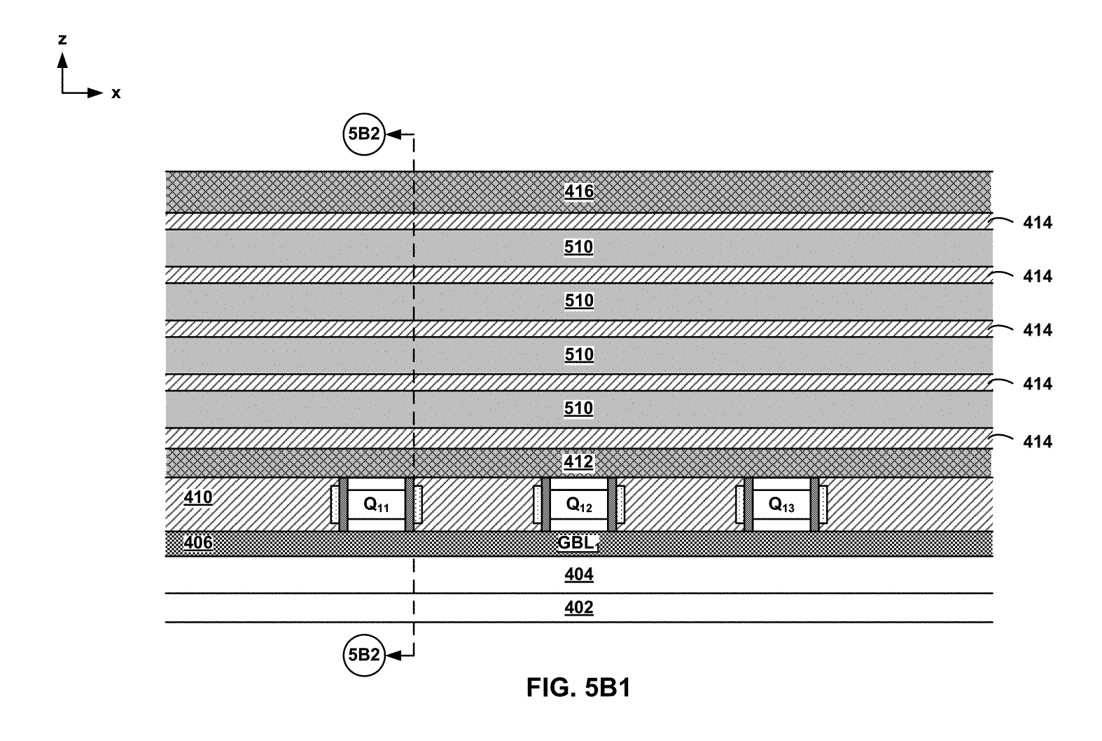

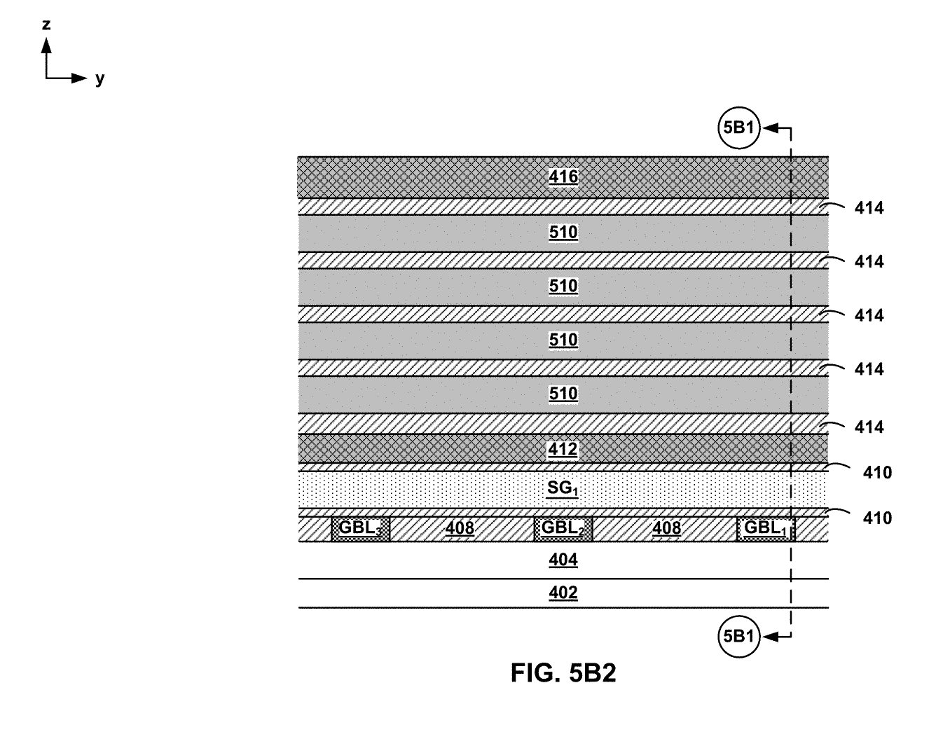

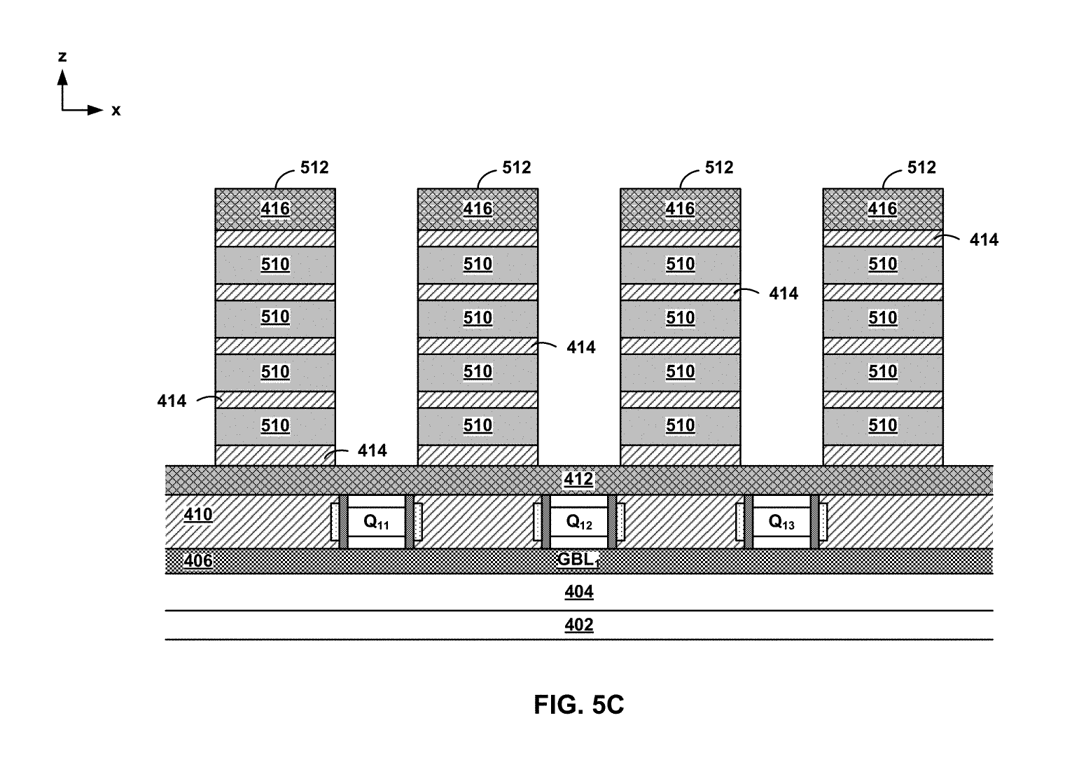

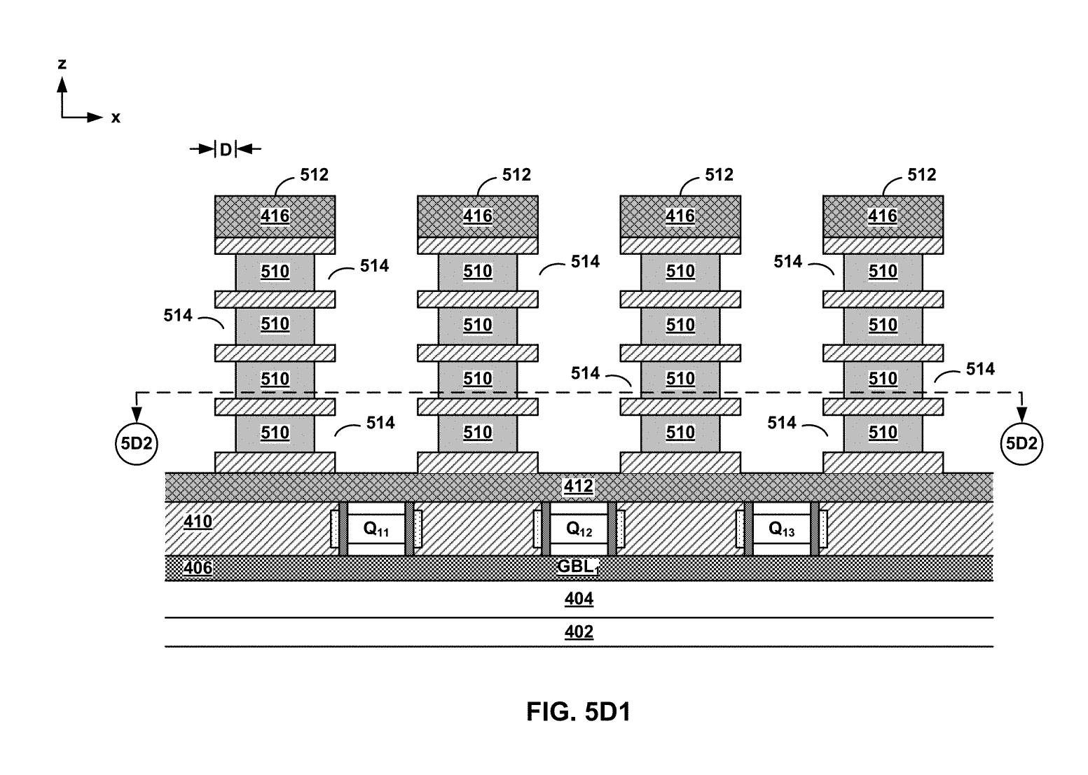

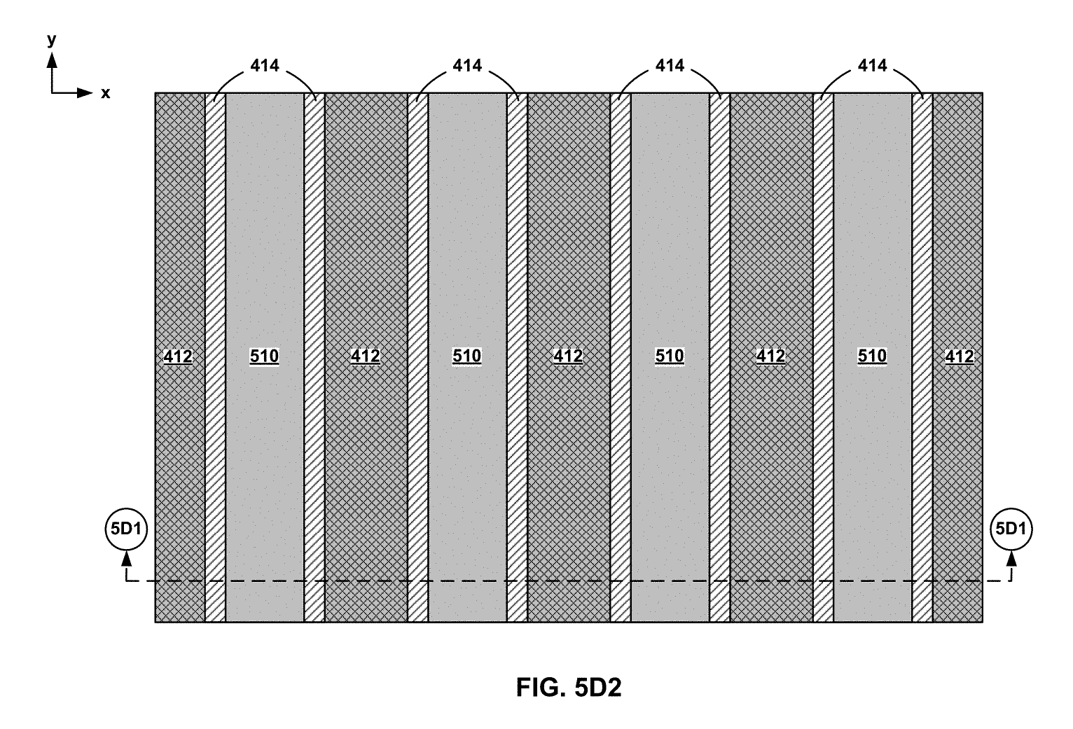

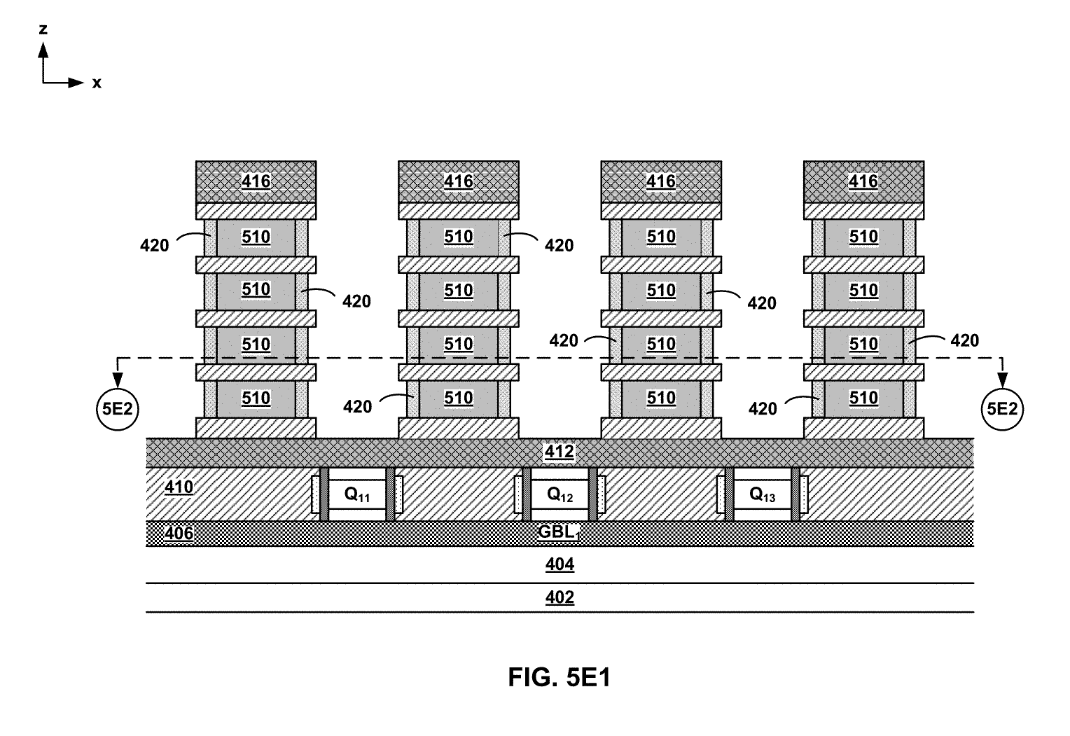

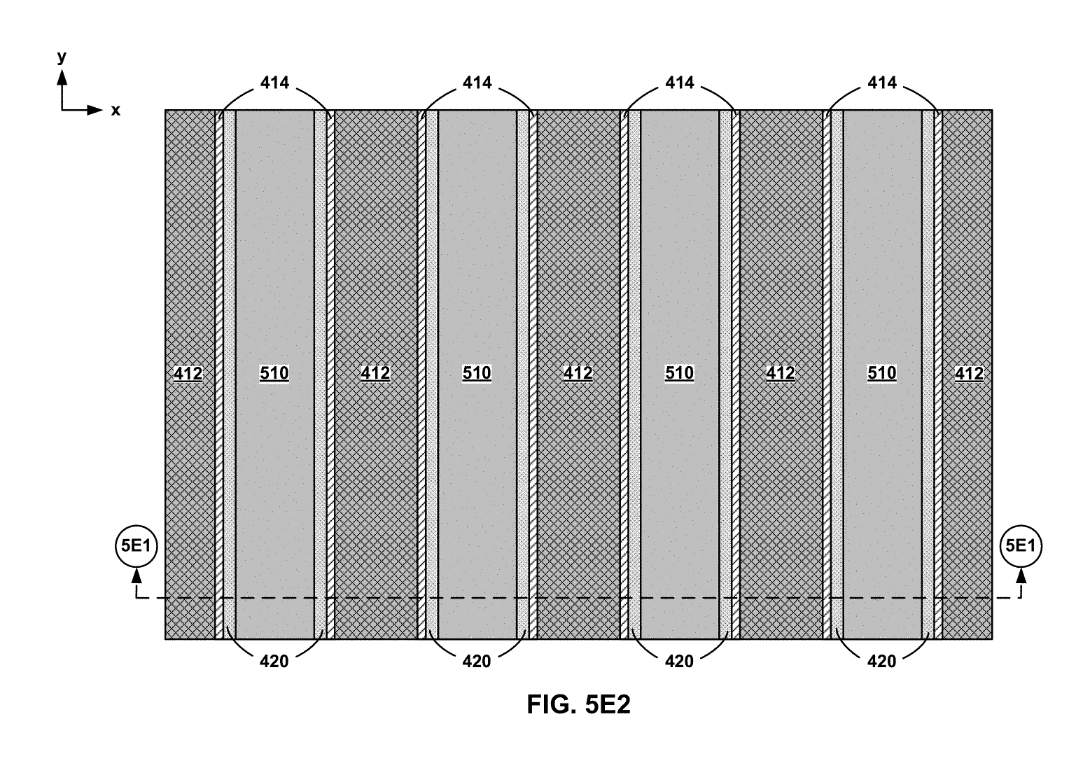

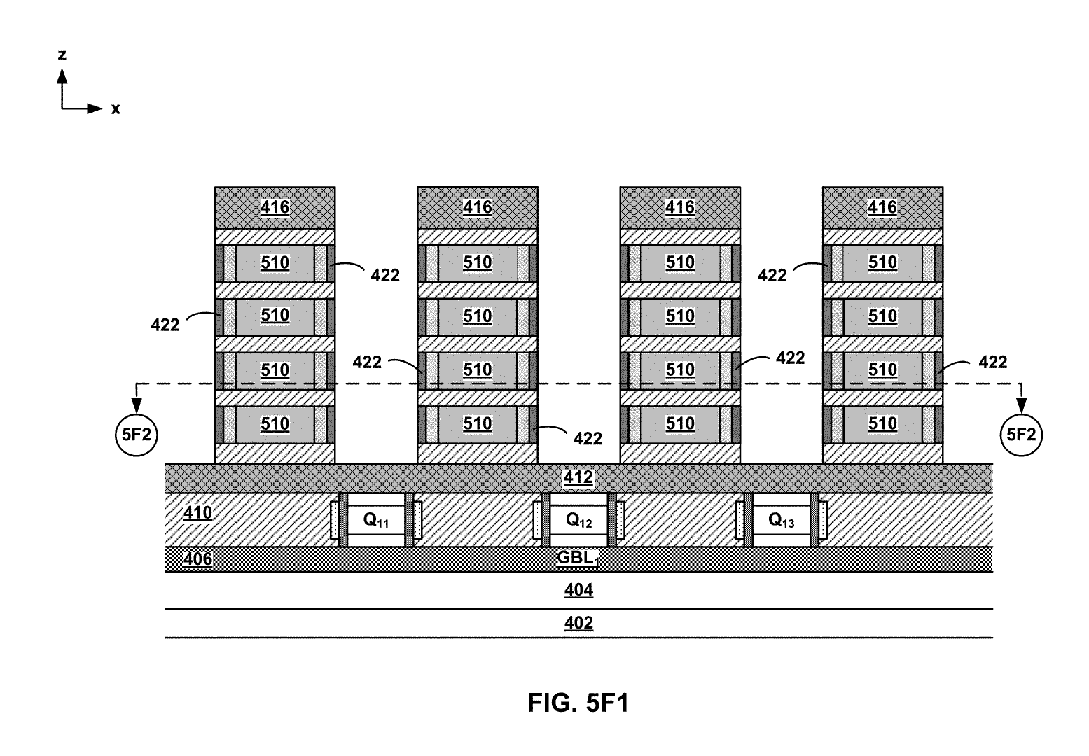

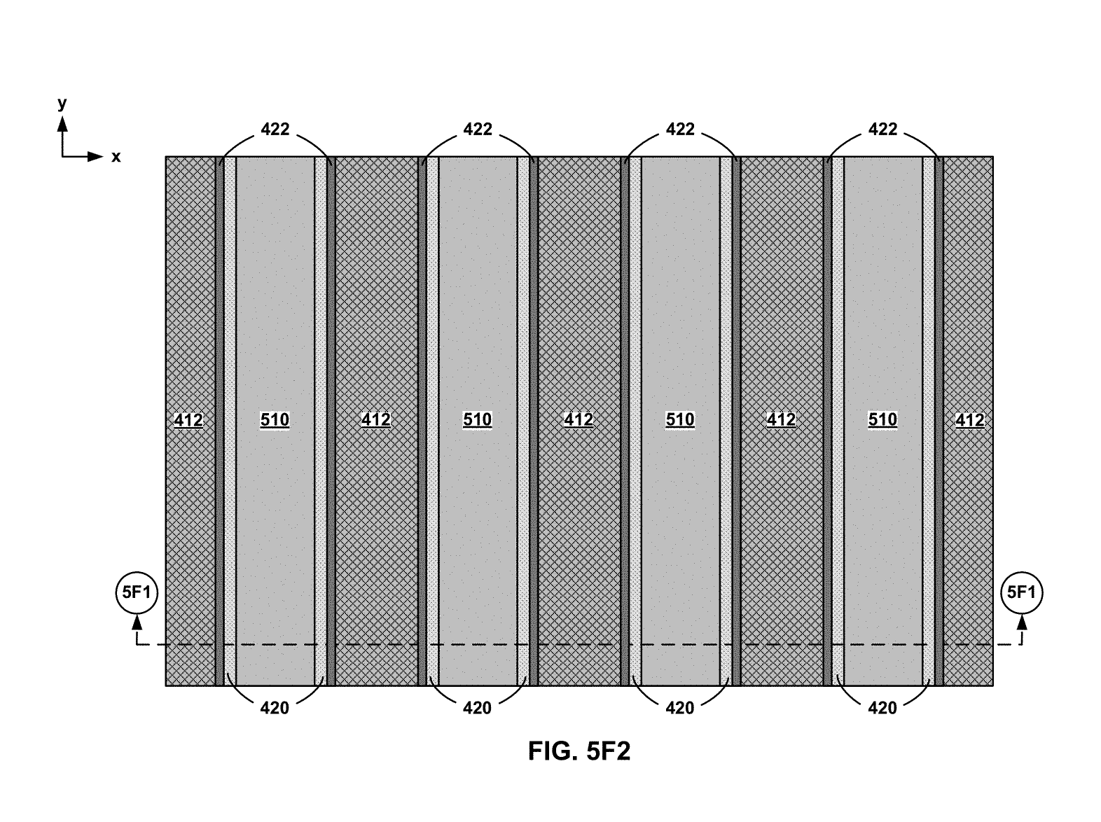

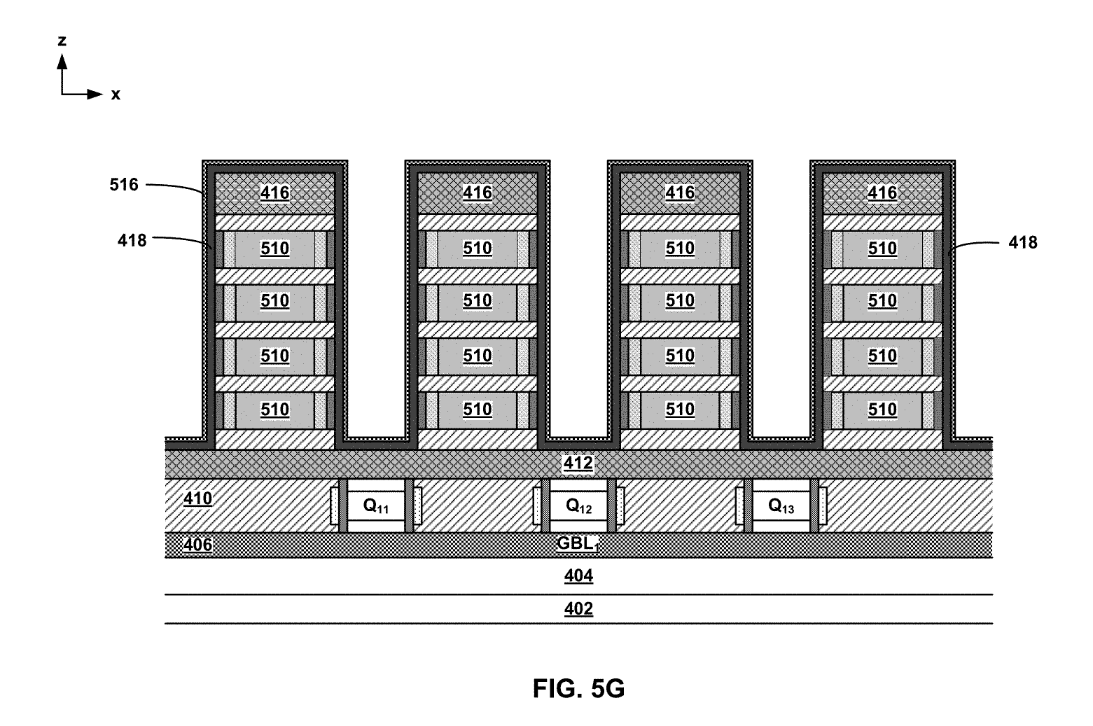

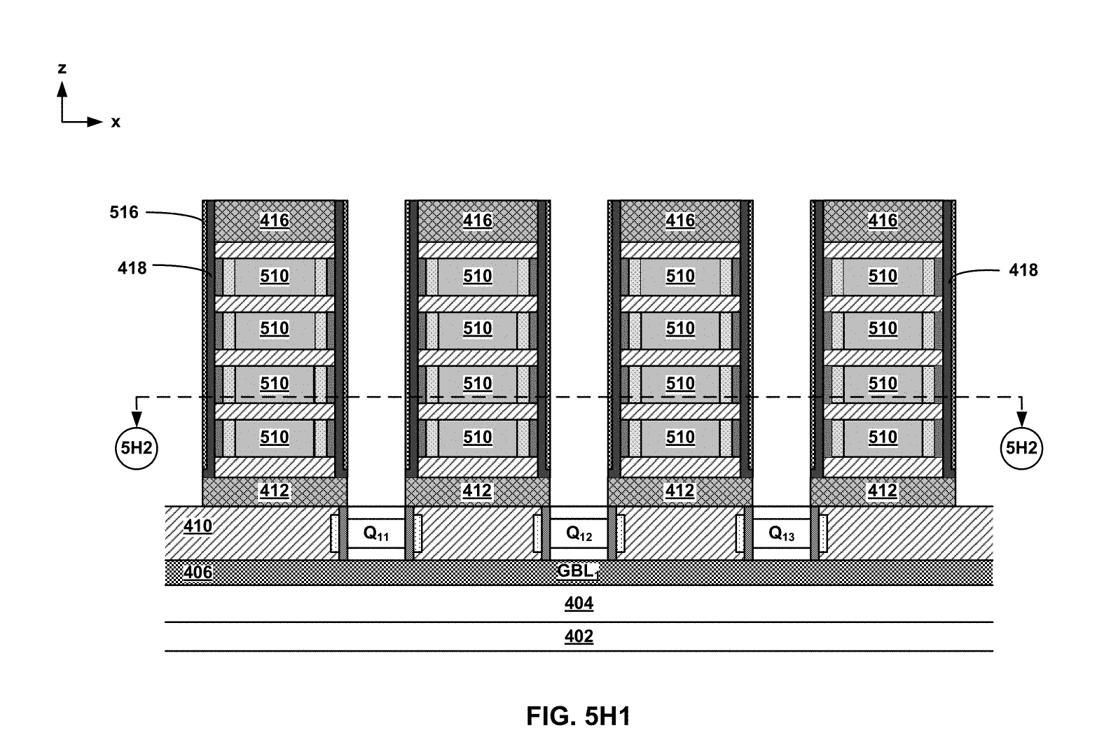

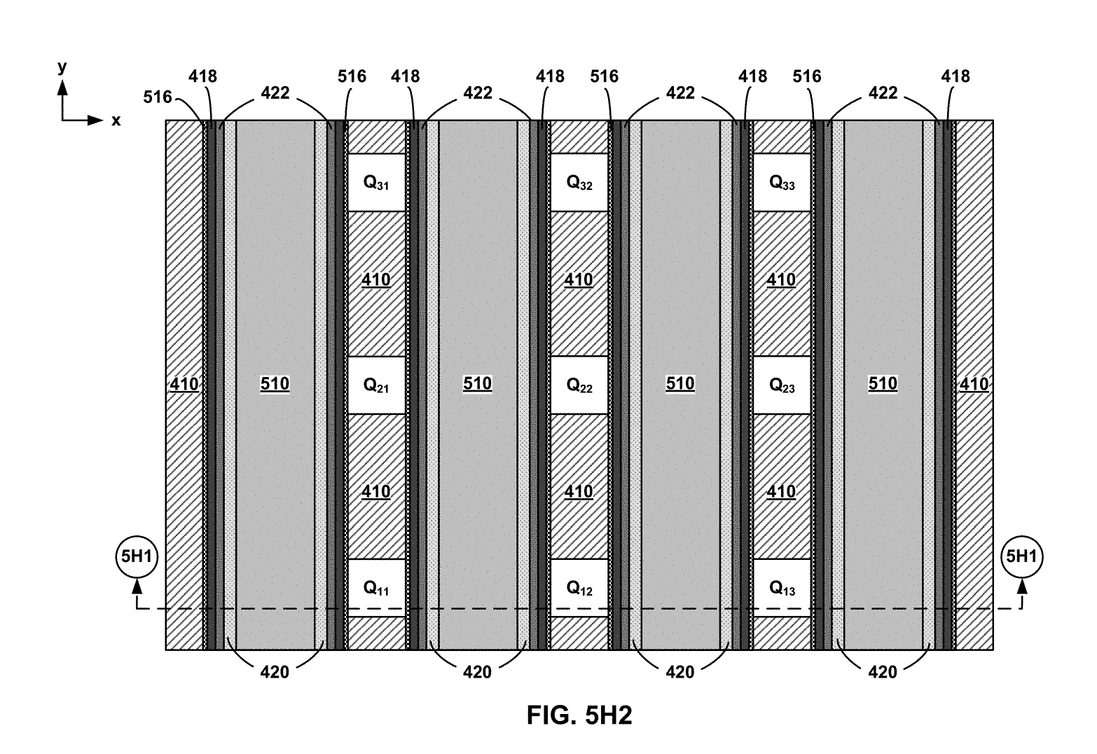

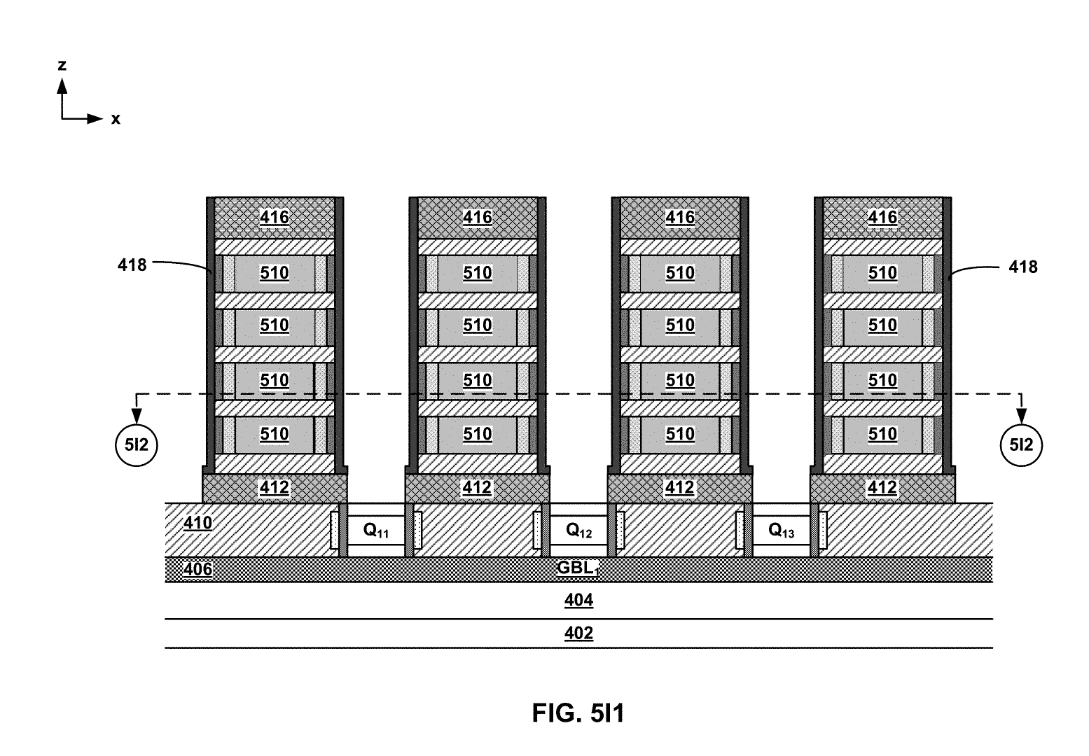

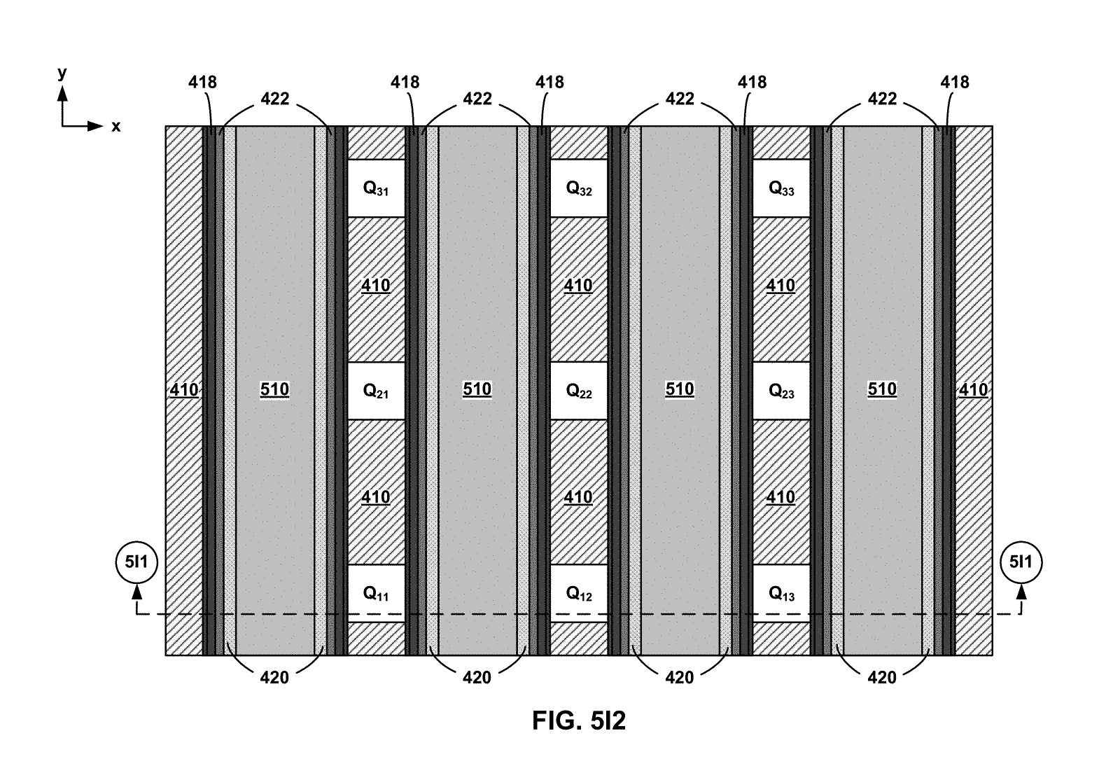

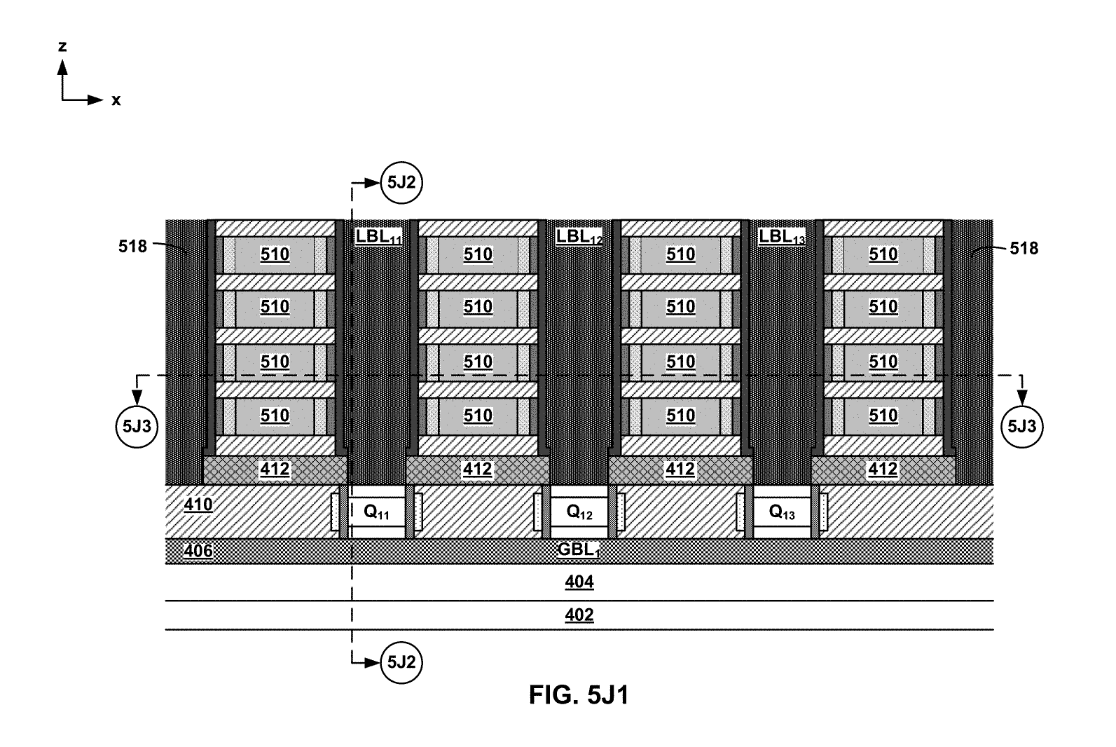

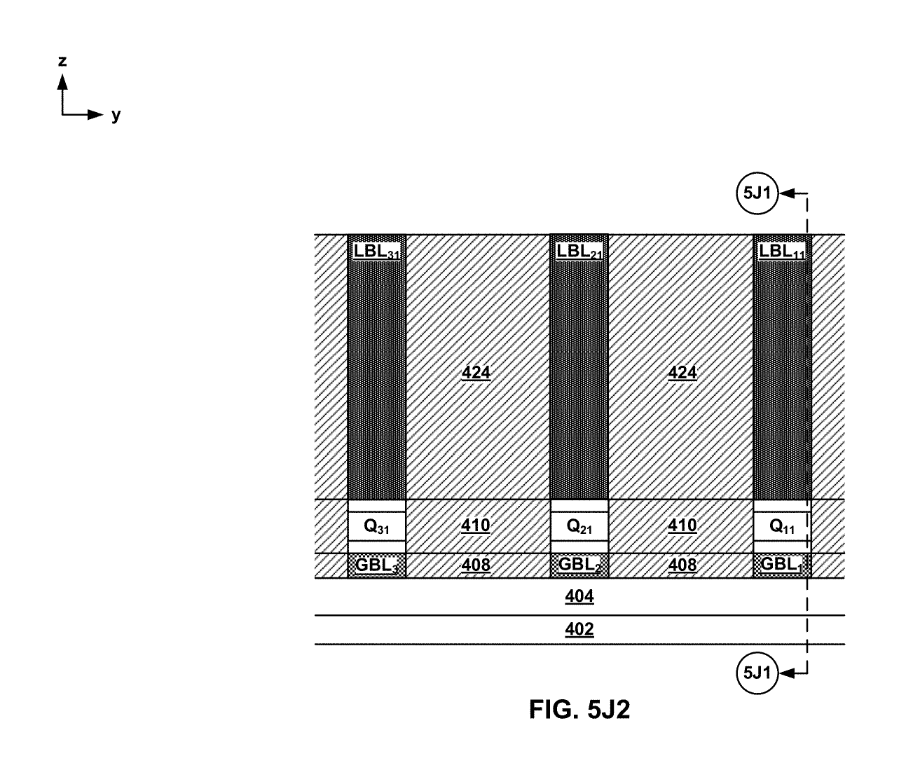

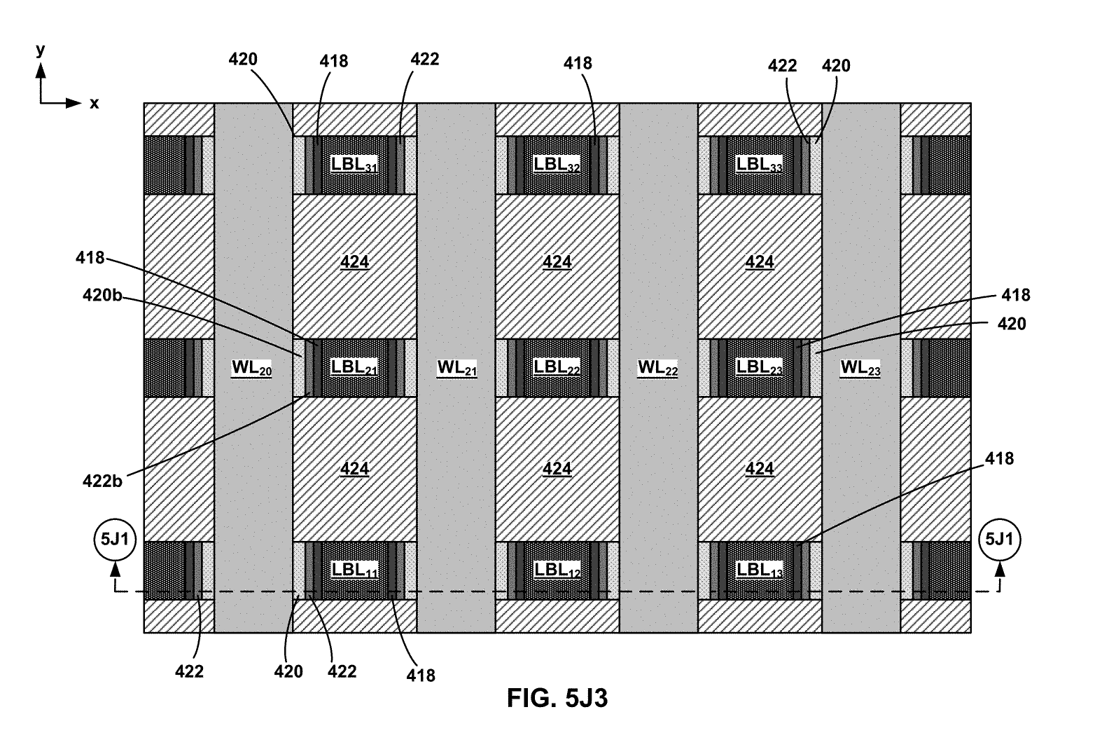

Referring now to FIGS. 5A1-5J3, an example method of forming a monolithic three-dimensional memory array, such as monolithic three-dimensional array 400 of FIGS. 4A-4E, is described.

With reference to FIGS. 5A1-5A2, substrate 402 is shown as having already undergone several processing steps. Substrate 402 may be any suitable substrate such as a silicon, germanium, silicon-germanium, undoped, doped, bulk, silicon-on-insulator (“SOI”) or other substrate with or without additional circuitry. For example, substrate 402 may include one or more n-well or p-well regions (not shown). Isolation layer 404 is formed above substrate 402. In some embodiments, isolation layer 404 may be a layer of silicon dioxide, silicon nitride, silicon oxynitride or any other suitable insulating layer.

Following formation of isolation layer 404, a conductive material layer 406 is deposited over isolation layer 404. Conductive material layer 406 may include any suitable conductive material such as tungsten or another appropriate metal, heavily doped semiconductor material, a conductive silicide, a conductive silicide-germanide, a conductive germanide, or the like deposited by any suitable method (e.g., CVD, PVD, etc.). In at least one embodiment, conductive material layer 406 may comprise between about 200 and about 2500 angstroms of tungsten. Other conductive material layers and/or thicknesses may be used. In some embodiments, an adhesion layer (not shown), such as titanium nitride or other similar adhesion layer material, may be disposed between isolation layer 404 and conductive material layer 406, and/or between conductive material layer 406 and subsequent vertically-oriented bit line select transistors layers.

Persons of ordinary skill in the art will understand that adhesion layers may be formed by PVD or another method on conductive material layers. For example, adhesion layers may be between about 20 and about 500 angstroms, and in some embodiments about 100 angstroms, of titanium nitride or another suitable adhesion layer such as tantalum nitride, tungsten nitride, tungsten, molybdenum, combinations of one or more adhesion layers, or the like. Other adhesion layer materials and/or thicknesses may be employed.

Following formation of conductive material layer 406, conductive material layer 406 is patterned and etched. For example, conductive material layer 406 may be patterned and etched using conventional lithography techniques, with a soft or hard mask, and wet or dry etch processing. In at least one embodiment, conductive material layer 406 is patterned and etched to form global bit lines GBL₁, GBL₂, GBL₃. Example widths for global bit lines GBL₁, GBL₂, GBL₃ and/or spacings between global bit lines GBL₁, GBL₂, GBL₃ range between about 480 angstroms and about 1000 angstroms, although other conductor widths and/or spacings may be used.

After global bit lines GBL₁, GBL₂, GBL₃ have been formed, a first dielectric material layer 408 is formed over substrate 402 to fill the voids between global bit lines GBL₁, GBL₂, GBL₃. For example, approximately 3000-7000 angstroms of silicon dioxide may be deposited on the substrate 402 and planarized using chemical mechanical polishing or an etchback process to form a planar surface 500. Other dielectric materials such as silicon nitride, silicon oxynitride, low K dielectrics, etc., and/or other dielectric material layer thicknesses may be used. Example low K dielectrics include carbon doped oxides, silicon carbon layers, or the like.

In other embodiments, global bit lines GBL₁, GBL₂, GBL₃ may be formed using a damascene process in which first dielectric material layer 408 is formed, patterned and etched to create openings or voids for global bit lines GBL₁, GBL₂, GBL₃. The openings or voids then may be filled with conductive layer 406 (and/or a conductive seed, conductive fill and/or barrier layer if needed). Conductive material layer 406 then may be planarized to form planar surface 500.

Following planarization, the semiconductor material used to form vertically-oriented bit line select transistors Q₁₁-Q₃₃ is formed over planarized top surface 500 of substrate 402. In some embodiments, each vertically-oriented bit line select transistor is formed from a polycrystalline semiconductor material such as polysilicon, an epitaxial growth silicon, a polycrystalline silicon-germanium alloy, polygermanium or any other suitable material. Alternatively, vertically-oriented bit line select transistors Q₁₁-Q₃₃ may be formed from a wide band-gap semiconductor material, such as ZnO, InGaZnO, or SiC, which may provide a high breakdown voltage, and typically may be used to provide junctionless FETs. Persons of ordinary skill in the art will understand that other materials may be used.

In some embodiments, each vertically-oriented bit line select transistor Q₁₁-Q₃₃ may include a first region (e.g., n+polysilicon), a second region (e.g., p polysilicon) and a third region (e.g., n+ polysilicon) to form drain/source, body, and source/drain regions, respectively, of a vertical FET. For example, a heavily doped n+ polysilicon layer 502 may be deposited on planarized top surface 500. In some embodiments, n+ polysilicon layer 502 is in an amorphous state as deposited. In other embodiments, n+ polysilicon layer 502 is in a polycrystalline state as deposited. CVD or another suitable process may be employed to deposit n+ polysilicon layer 502.

In an embodiment, n+ polysilicon layer 502 may be formed, for example, from about 100 to about 500 angstroms, of phosphorus or arsenic doped silicon having a doping concentration of about 10²¹ cm⁻³. Other layer thicknesses, doping types and/or doping concentrations may be used. N+ polysilicon layer 502 may be doped in situ, for example, by flowing a donor gas during deposition. Other doping methods may be used (e.g., implantation).

After deposition of n+ silicon layer 502, a doped p-type silicon layer 504 may be formed over n+ polysilicon layer 502. P-type silicon may be either deposited and doped by ion implantation or may be doped in situ during deposition to form a p-type silicon layer 504. For example, an intrinsic silicon layer may be deposited on n+ polysilicon layer 502, and a blanket p-type implant may be employed to implant boron a predetermined depth within the intrinsic silicon layer. Example implantable molecular ions include BF₂, BF₃, B and the like. In some embodiments, an implant dose of about 1-10×10¹³ ions/cm² may be employed. Other implant species and/or doses may be used. Further, in some embodiments, a diffusion process may be employed. In an embodiment, the resultant p-type silicon layer 504 has a thickness of from about 800 to about 4000 angstroms, although other p-type silicon layer sizes may be used.

Following formation of p-type silicon layer 504, a heavily doped n+ polysilicon layer 506 is deposited on p-type silicon layer 504. In some embodiments, n+ polysilicon layer 506 is in an amorphous state as deposited. In other embodiments, n+ polysilicon layer 506 is in a polycrystalline state as deposited. CVD or another suitable process may be employed to deposit n+ polysilicon layer 506.

In an embodiment, n+ polysilicon layer 506 may be formed, for example, from about 100 to about 500 angstroms of phosphorus or arsenic doped silicon having a doping concentration of about 10²¹ cm⁻³. Other layer thicknesses, doping types and/or doping concentrations may be used. N+ polysilicon layer 506 may be doped in situ, for example, by flowing a donor gas during deposition. Other doping methods may be used (e.g., implantation). Persons of ordinary skill in the art will understand that silicon layers 502, 504 and 506 alternatively may be doped p+/n/p+, respectively, or may be doped with a single type of dopant to produce junctionless-FETs.

Following formation of n+ polysilicon layer 506, silicon layers 502, 504 and 506 are patterned and etched to form vertical transistor pillars. For example, silicon layers 502, 504 and 506 may be patterned and etched using conventional lithography techniques, with wet or dry etch processing. In an embodiment, silicon layers 502, 504 and 506 are patterned and etched to form vertical transistor pillars disposed above global bit lines GBL₁, GBL₂, GBL₃. The vertical transistor pillars will be used to form vertically-oriented bit line select transistors Q₁₁-Q₃₃.

Silicon layers 502, 504 and 506 may be patterned and etched in a single pattern/etch procedure or using separate pattern/etch steps. Any suitable masking and etching process may be used to form vertical transistor pillars. For example, silicon layers may be patterned with about 1 to about 1.5 micron, more preferably about 1.2 to about 1.4 micron, of photoresist (“PR”) using standard photolithographic techniques. Thinner PR layers may be used with smaller critical dimensions and technology nodes. In some embodiments, an oxide hard mask may be used below the PR layer to improve pattern transfer and protect underlying layers during etching.

In some embodiments, after etching, the vertical transistor pillars may be cleaned using a dilute hydrofluoric/sulfuric acid clean. Such cleaning may be performed in any suitable cleaning tool, such as a Raider tool, available from Semitool of Kalispell, Mont. Example post-etch cleaning may include using ultra-dilute sulfuric acid (e.g., about 1.5 1.8 wt %) for about 60 seconds and/or ultra-dilute hydrofluoric (“HF”) acid (e.g., about 0.4-0.6 wt %) for 60 seconds. Megasonics may or may not be used. Other clean chemistries, times and/or techniques may be employed.

A gate dielectric material layer 426 is deposited conformally over substrate 402, and forms on sidewalls of the vertical transistor pillars. For example, between about 30 angstroms to about 100 angstroms of silicon dioxide may be deposited. Other dielectric materials such as silicon nitride, silicon oxynitride, low K dielectrics, etc., and/or other dielectric material layer thicknesses may be used.

Gate electrode material is deposited over the vertical transistor pillars and gate dielectric material layer 426 to fill the voids between the vertical transistor pillars. For example, approximately 10 nm to about 20 nm of titanium nitride or other similar metal, a highly-doped semiconductor, such as n+ polysilicon, p+ polysilicon, or other similar conductive material may be deposited. The as-deposited gate electrode material is subsequently etched back to form row select lines SG₁, SG₂, SG₃.

A second dielectric material layer 410 is deposited over substrate 402. For example, approximately 5000 to about 8000 angstroms of silicon dioxide may be deposited and planarized using chemical mechanical polishing or an etch-back process to form planar top surface 508, resulting in the structure shown in FIGS. 5A1-5A3. Other dielectric materials and/or thicknesses may be used.

Planar surface 508 includes exposed top surfaces of vertically-oriented bit line select transistors Q₁₁-Q₃₃ and gate dielectric material layer 426 separated by second dielectric material layer 410. Other dielectric materials such as silicon nitride, silicon oxynitride, low K dielectrics, etc., and/or other dielectric material layer thicknesses may be used. Example low K dielectrics include carbon doped oxides, silicon carbon layers, or the like.

Next, a first etch stop layer 412 is formed over substrate 402. First etch stop layer 412 may include any suitable etch stop layer formed by any suitable method (e.g., CVD, PVD, etc.). In an embodiment, first etch stop layer 412 may include between about 50 angstroms and about 500 angstroms of silicon nitride. Other etch stop layer materials and/or thicknesses may be used.

Alternating layers of third dielectric material layer 414 and a conductive material layer 510 are formed over substrate 402. In an embodiment, each third dielectric material layer 414 may be between about 200 angstroms and about 500 angstroms of SiO₂, each conductive material layer 510 may be between about 250 angstroms and about 400 angstroms of a metal having a first work function φ1 greater than about 4.8 eV. In embodiments, each conductive material layer 510 may include one or more of ruthenium, ruthenium oxide, rhodium, rhenium, platinum, iridium or other similar material. Other dielectric materials and/or thicknesses, other metal materials and/or thicknesses may be used and other work function values may be used.

In an embodiment, four conductive material layers 510 are formed over substrate 402. More or fewer than four conductive material layers 510 may be used.

Next, a second etch stop layer 416 is formed over substrate 402, resulting in the structure shown in FIGS. 5B1-5B2. Second etch stop layer 416 may include any suitable etch stop layer formed by any suitable method (e.g., CVD, PVD, etc.). In an embodiment, second etch stop layer 416 may comprise between about 50 angstroms and about 500 angstroms of silicon nitride. Other etch stop layer materials and/or thicknesses may be used.

Next, second etch stop layer 416, third dielectric material layers 414, and conductive material layers 510 are patterned and etched to form rows 512 of multi-layer word lines WL₁₀, WL₁₁, . . . , WL₄₃, resulting in the structure shown in FIG. 5C. Each of rows 512 of word lines WL₁₀, WL₁₁, . . . , WL₄₃ may be between about 200 angstroms and about 1000 angstroms wide, although other widths may be used.

Next, an etch is performed to form voids 514 at ends of conductive material layers 510, resulting in the structure shown in FIGS. 5D1-5D2. Each of voids 514 may have a depth D of between about 100 angstroms and about 200 angstroms, although other lengths may be used.

A semiconductor material 420 is deposited conformally over rows 512, filling voids 514. In an embodiment, semiconductor material 420 may be between about 50 angstroms and about 100 angstroms of amorphous silicon. Other semiconductor materials and/or thicknesses may be used. An anisotropic etch is used to remove lateral portions of semiconductor material 420, leaving only sidewall portions of semiconductor material 420 in voids 514, resulting in the structure shown in FIG. 5E1-5E2.

A metal material 422 is deposited conformally over rows 512, filling voids 514. In an embodiment, metal material 422 may be between about 50 angstroms and about 100 angstroms of titanium nitride. Other metal materials, such as tantalum, tantalum nitride, tin oxide or other similar metal material, and/or other thicknesses may be used. An anisotropic etch is used to remove lateral portions of metal material 422, leaving only sidewall portions of metal material 422 in voids 514, resulting in the structure shown in FIGS. 5F1-5F2.

A non-volatile memory material layer 418 is deposited conformally over rows 512. Non-volatile memory material 418 may include, for example, an oxide layer, a reversible resistance-switching material (e.g., a metal oxide layer such as nickel oxide, hafnium oxide, or other similar metal oxide material, a phase change material or other similar reversible resistance-switching material), or a charge trapping layer (e.g., a layer of silicon nitride).

For example, between about 20 angstroms to about 1000 angstroms of hafnium oxide (HfO₂) may be deposited. Other non-volatile memory materials such as Al₂O₃, HfSiOₓ, HfSiOₓN_{y}, HfAlOₓ, Nb₂O₅, Ta₂O₅, ZrO₂, Cr₂O₃, Fe₂O₃, Ni₂O₃, CO₂O₃, WO₃, TiO₂, SrZrO₃, SrTiO₃, or other suitable non-volatile memory materials, etc., and/or other non-volatile memory material layer thicknesses may be used. Non-volatile memory material layer 418 may be a single layer of a single non-volatile memory material, or may be multiple layers of one or more non-volatile memory materials.

Next, a polysilicon material layer 516 is conformally deposited over non-volatile memory material layer 418. For example, between about 10 angstroms to about 200 angstroms of polysilicon may be deposited on substrate 402, resulting in the structure shown in FIG. 5G. Other materials such n+ polysilicon, p+ polysilicon, and/or other dielectric material layer thicknesses may be used.

An anisotropic etch is used to remove lateral portions of polysilicon material layer 516, non-volatile memory material layer 418 and first etch stop layer 412, leaving only sidewall portions of polysilicon material layer 516 and non-volatile memory material layer 418, and exposing top surfaces of bit line select transistors Q₁₁-Q₃₁, resulting in the structure shown in FIGS. 5H1-5H2.

Next, polysilicon material layer 516 is removed, for example by a wet etch process, exposing non-volatile memory material layer 418, and resulting in the structure shown in FIGS. 511-512.

A conductive material 518 is deposited over substrate 402. Conductive material layer 518 may include any suitable conductive material such as heavily doped semiconductor material, tungsten or another appropriate metal, a conductive silicide, a conductive silicide-germanide, a conductive germanide, or the like deposited by any suitable method (e.g., CVD, PVD, etc.). For example, between about 1000 angstroms to about 5000 angstroms of heavily doped polysilicon may be deposited and planarized using chemical mechanical polishing or an etch-back process. Other conductive materials and/or thicknesses may be used.

Conductive material 518, non-volatile memory material layer 418, metal material 422 and semiconductor material 420 are then patterned and etched to form vertical bit lines LBL₁₁-LBL₃₃, vertical strips of a non-volatile memory material 418, strips of a semiconductor material 420, and strips of a metal material 422.

A dielectric material 424, such as silicon dioxide, may then be deposited over substrate 402, filling the voids between vertical bit lines LBL₁₁-LBL₃₃, and then planarized using chemical mechanical polishing or an etch-back process, resulting in the structure shown in FIGS. 5J1-5J3.

Thus, as described above, one embodiment of the disclosed technology includes a method that includes forming a bit line above a substrate, forming a word line above the substrate, and forming a non-volatile memory cell between the bit line and the word line. The non-volatile memory cell includes a non-volatile memory material coupled in series with an isolation element. The isolation element includes a first portion disposed between a first electrode and a second electrode, the first electrode includes a first material having a first work function, the second electrode includes a second material having second work function, and the first work function does not equal the second work function.

One embodiment of the disclosed technology includes a method including forming a vertical bit line disposed in a first direction above a substrate, forming a word line disposed in a second direction above the substrate, the second direction perpendicular to the first direction, and forming a non-volatile memory cell at an intersection of the vertical bit line and the word line. The non-volatile memory cell includes a non-volatile memory material coupled in series with an isolation element.

The isolation element includes a semiconductor material disposed between a first electrode and a second electrode, the first electrode includes a first metal having a first work function, the second electrode includes a second metal having second work function, and the first work function does not equal the second work function.

One embodiment of the disclosed technology includes a method that includes forming a bit line above a substrate, forming a word line above the substrate, and forming a non-volatile memory cell between the bit line and the word line. The non-volatile memory cell includes a non-volatile memory material coupled in series with a metal-semiconductor-metal isolation element. The metal-semiconductor-metal isolation element has an ON-state current density of greater than about 1-10 MA/cm², an OFF-state leakage current of less than about 10 nA, an ON/OFF current ratio of greater than about 500, and a low-leakage voltage zone of between about 0 volts and about 1.2 volts.

For purposes of this document, each process associated with the disclosed technology may be performed continuously and by one or more computing devices. Each step in a process may be performed by the same or different computing devices as those used in other steps, and each step need not necessarily be performed by a single computing device.

For purposes of this document, reference in the specification to “an embodiment,” “one embodiment,” “some embodiments,” or “another embodiment” may be used to described different embodiments and do not necessarily refer to the same embodiment.

For purposes of this document, a connection can be a direct connection or an indirect connection (e.g., via another part).

For purposes of this document, the term “set” of objects may refer to a “set” of one or more of the objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A method comprising:
forming a bit line above a substrate;
forming a word line above the substrate; and
forming a non-volatile memory cell between the bit line and the word line, the non-volatile memory cell comprising a non-volatile memory material coupled in series with an isolation element,
wherein:
the isolation element comprises a first portion disposed between a first electrode and a second electrode;
the first electrode comprises a first material having a first work function;
the second electrode comprises a second material having second work function; and
the first work function does not equal the second work function.

2. The method of claim 1, wherein the first portion comprises a semiconductor material.

3. The method of claim 2, wherein the semiconductor material comprises one or more of silicon, silicon germanium, and germanium.

4. The method of claim 1, wherein the first material comprises a first metal.

5. The method of claim 1, wherein the first material comprises one or more of ruthenium, ruthenium oxide, rhodium, rhenium, platinum, and iridium.

6. The method of claim 1, wherein the second material comprises a second metal.

7. The method of claim 1, wherein the second material comprises one or more of titanium nitride, tantalum, tantalum nitride, tungsten nitride, tin oxide, indium tin oxide

8. The method of claim 1, wherein the word line comprises the first electrode or the second electrode.

9. The method of claim 1, wherein the non-volatile memory material comprises one of a reversible resistance-switching material, a phase change material, and a charge trapping layer.

10. The method of claim 1, wherein the non-volatile memory material comprises one or more of HfO₂, Al₂O₃, HfSiOₓ, HfSiOₓN_{y}, HfAlOₓ, Nb₂O₅, Ta₂O₅, ZrO₂, Cr₂O₃, Fe₂O₃, Ni₂O₃, CO₂O₃, WO₃, TiO₂, SrZrO₃, SrTiO₃.

11. A method comprising:
forming a vertical bit line disposed in a first direction above a substrate;
forming a word line disposed in a second direction above the substrate, the second direction perpendicular to the first direction; and
forming a non-volatile memory cell at an intersection of the vertical bit line and the word line, the non-volatile memory cell comprising a non-volatile memory material coupled in series with an isolation element,
wherein:
the isolation element comprises a semiconductor material disposed between a first electrode and a second electrode;
the first electrode comprises a first metal having a first work function;
the second electrode comprises a second metal having second work function; and
the first work function does not equal the second work function.

12. The method of claim 11, wherein the semiconductor material comprises one or more of silicon, silicon germanium, and germanium.

13. The method of claim 11, wherein the first metal comprises one or more of ruthenium, ruthenium oxide, rhodium, rhenium, platinum, and iridium.

14. The method of claim 11, wherein the second metal comprises one or more of titanium nitride, tantalum, tantalum nitride, tungsten nitride, tin oxide, indium tin oxide

15. The method of claim 11, wherein the word line comprises the first electrode or the second electrode.

16. The method of claim 11, wherein the non-volatile memory material comprises one of a reversible resistance-switching material, a phase change material, and a charge trapping layer.

17. The method of claim 11, wherein the non-volatile memory material comprises one or more of HfO₂, Al₂O₃, HfSiOₓ, HfSiOₓN_{y}, HfAlOₓ, Nb₂O₅, Ta₂O₅, ZrO₂, Cr₂O₃, Fe₂O₃, Ni₂O₃, Co₂O₃, WO₃, TiO₂, SrZrO₃, SrTiO₃.

18. A method comprising:
forming a bit line above a substrate;
forming a word line above the substrate; and
forming a non-volatile memory cell between the bit line and the word line, the non-volatile memory cell comprising a non-volatile memory material coupled in series with a metal-semiconductor-metal isolation element comprising a first electrode comprising a first material having a first work function, and a second electrode comprising a second material having second work function, wherein the first work function does not equal the second work function, wherein the metal-semiconductor-metal isolation element comprises an ON-state current density of greater than about 1-10 MA/cm², an OFF-state leakage current of less than about 10 nA, an ON/OFF current ratio of greater than about 500, and a low-leakage voltage zone of between about 0 volts and about 1.2 volts.

19. The method of claim 18, wherein the non-volatile memory material comprises one of a reversible resistance-switching material, a phase change material, and a charge trapping layer.

20. The method of claim 18, wherein the non-volatile memory material comprises one or more of HfO₂, Al₂O₃, HfSiOₓ, HfSiOₓN_{y}, HfAlOₓ, Nb₂O₅, Ta₂O₅, ZrO₂, Cr₂O₃, Fe₂O₃, Ni₂O₃, CO₂O₃, WO₃, TiO₂, SrZrO₃, SrTiO₃.
